(19) United States
(12) Patent Application Publication
(10) Pub. No.: US 2021/0217888 A1
(43) Pub. Date: Jul. 15, 2021

(54) SEMICONDUCTOR DEVICE HAVING A TRANSISTOR

(71) Applicant: RENESAS ELECTRONICS CORPORATION, Tokyo (JP)

(72) Inventors: Atsushi SAKAI, Tokyo (JP); Katsumi EIKYU, Tokyo (JP); Satoshi EGUCHI, Ibaraki (JP); Nobuo MACHIDA, Ibaraki (JP); Koichi ARAI, Ibaraki (JP); Yasuhiro OKAMOTO, Ibaraki (JP); Kenichi HISADA, Ibaraki (JP); Yasunori YAMASHITA, Ibaraki (JP)

(21) Appl. No.: 17/216,136

(22) Filed: Mar. 29, 2021

Related U.S. Application Data
(63) Continuation of application No. 16/192,480, filed on Nov. 15, 2018.

(30) Foreign Application Priority Data
Dec. 27, 2017 (JP) 2017-251068

(51) Int. Cl. H01L 29/78; H01L 29/16; H01L 29/66; H01L 29/423; H01L 29/08

(52) U.S. Cl. CPC H01L 29/7813; H01L 29/1608; H01L 29/0865; H01L 29/4236; H01L 29/66734; H01L 29/66068

(57) ABSTRACT

To improve characteristics of a semiconductor device. A first p-type semiconductor region having an impurity of a conductivity type opposite from that of a drift layer is arranged in the drift layer below a trench, and a second p-type semiconductor region is further arranged that is spaced at a distance from a region where the trench is formed as seen from above and that has the impurity of the conductivity type opposite from that of the drift layer. The second p-type semiconductor region is configured by a plurality of regions arranged at a space in a Y direction (depth direction in the drawings). Thus, it is possible to reduce the specific on-resistance while maintaining the breakdown voltage of the gate insulating film by providing the first and second p-type semiconductor regions and further by arranging the second p-type semiconductor region spaced by the space.

### CROSS-REFERENCE TO RELATED APPLICATIONS

This is a Continuation of U.S. patent application Ser. No. 16/192,480 filed on Nov. 15, 2018 which claims the benefit of Japanese Patent Application No. 2017-251068 filed on Dec. 27, 2017 including the specification, drawings and abstract are incorporated herein by reference in their entirety.

### BACKGROUND

The present invention relates to a semiconductor device, which is preferably applicable to a semiconductor device that includes silicon carbide (SiC), among others.

It is considered to use a semiconductor device including a SiC substrate for a semiconductor device having a transistor. For example, when the SiC substrate is used for the power transistor, breakdown voltage is increased because SiC has a larger bandgap compared to silicon (Si).

For example, Japanese Unexamined Patent Application Publication No. HEI09(1997)-191109 discloses that a depletion layer expands from a p-type base layer toward a drain electrode side in proportion to increase of applied voltage in an off-state, and the p-type buried layer fixes the electric field intensity in the depletion layer by punch-through phenomenon when the depletion layer reaches the p-type buried layer, thereby suppressing increase of the electric field intensity. The disclosed technology allows for reducing voltage drop during an on-state despite its high breakdown voltage by increasing carrier density of an n-type base layer in a range having a limit value of the electric field intensity exceeding the maximum electric field intensity at this time and thereby reducing a specific on-resistance.

Japanese Unexamined Patent Application Publication No. 2014-138026 discloses a technology of providing both an element structure and a termination structure on an outer edge, thereby reducing the size of the MOSFET while increasing the breakdown voltage. The MOSFET includes a relaxing region partially provided on an interface between a lower range and an upper range of an epitaxial film.

### SUMMARY

The inventors are engaged in research and development of semiconductor devices that employ silicon carbide (SiC), and diligently study on improving characteristics of the semiconductor devices.

As described above, the breakdown voltage can be increased because SiC has a larger bandgap compared to silicon (Si). However, a MISFET, a semiconductor device using SiC, has a problem of the breakdown voltage of agate insulating film emerging as the breakdown voltage of SiC increases. That is, there may be a problem that the gate insulating film breaks down before SiC breaks down.

Thus, as described later, the breakdown voltage of the gate insulating film can be improved by arranging an electric field relaxing layer near the gate insulating film to relax the electric field near the gate insulating film. However, the electric field relaxing layer makes an electric current path narrower, which may increase the specific on-resistance. That is, there is a trade-off relationship between increase of the breakdown voltage of the gate insulating film and decrease of the specific on-resistance.

Therefore, it is desired to consider a configuration of a semiconductor device (MISFET) allowing for reducing the specific on-resistance while increasing the breakdown voltage of the gate insulating film.

Other problems and novel features will become apparent from the following description and accompanying drawings.

Outlines of representative embodiments among those disclosed herein are briefly described below.

A semiconductor device according to an embodiment disclosed herein includes a drift layer, a channel layer, a source region, a trench penetrating the channel layer to reach the drift layer and contacting the source region, a gate insulating film formed over an inner wall of the trench, and a gate electrode that fills the trench. Furthermore, the semiconductor device includes, in the drift layer below the trench, a first semiconductor region formed in a position overlapping a region where the trench is formed as seen from above and having an impurity of a conductivity type opposite from that of the drift layer, and in the drift layer below the trench, a second semiconductor region spaced from the region where the trench is formed as seen from above and having an impurity of the conductivity type opposite from that of the drift layer. The second semiconductor region is configured by a plurality of second regions arranged at a second space in a first direction.

A semiconductor device according to an embodiment disclosed herein includes a drift layer, a channel layer, a source region, a trench penetrating the channel layer to reach the drift layer and contacting the source region, a gate insulating film formed over an inner wall of the trench, and a gate electrode that fills the trench. Furthermore, the semiconductor device includes, in the drift layer below the trench, a first semiconductor region formed in a position overlapping a region where the trench is formed as seen from above and having an impurity of a conductivity type opposite from that of the drift layer, and in the drift layer below the trench, a second semiconductor region spaced from the region where the trench is formed as seen from above and having an impurity of a conductivity type opposite from that of the drift layer. The first semiconductor region is configured by a plurality of first regions arranged at a first space in a first direction.

A semiconductor device according to an embodiment disclosed herein includes a drift layer, a channel layer, a source region, a trench penetrating the channel layer to reach the drift layer and contacting the source region, a gate insulating film formed over an inner wall of the trench, and a gate electrode that fills the trench. Furthermore, the semiconductor device includes, in the drift layer below the trench, a first semiconductor region formed in a position overlapping a region where the trench is formed as seen from above and having an impurity of a conductivity type opposite from that of the drift layer, and in the drift layer below the trench, a second semiconductor region spaced from the region where the trench is formed as seen from above and having an impurity of a conductivity type opposite from that of the drift layer. The first semiconductor region is formed in a location deeper than the second semiconductor region.

The semiconductor device according to representative embodiments disclosed herein and described below makes it possible to improve characteristics of the semiconductor device.

### BRIEF DESCRIPTION OF THE DRAWINGS

FIG. 1A is a cross-sectional view showing a configuration of a semiconductor device according to a first embodiment;

FIG. 1B is a cross-sectional view showing the configuration of the semiconductor device according to the first embodiment;

FIG. 2 is a plan view showing the configuration of the semiconductor device according to the first embodiment;

FIG. 3A is a plan view showing the configuration of the semiconductor device according to the first embodiment;

FIG. 3B is a plan view showing the configuration of the semiconductor device according to the first embodiment;

FIG. 4 is a cross-sectional view showing a manufacturing process of the semiconductor device according to the first embodiment;

FIG. 5 is a cross-sectional view showing the manufacturing process of the semiconductor device according to the first embodiment;

FIG. 6 is a plan view showing the manufacturing process of the semiconductor device according to the first embodiment;

FIG. 7 is a cross-sectional view showing the manufacturing process of the semiconductor device according to the first embodiment;

FIG. 8 is a cross-sectional view showing the manufacturing process of the semiconductor device according to the first embodiment;

FIG. 9 is a cross-sectional view showing the manufacturing process of the semiconductor device according to the first embodiment;

FIG. 10 is a cross-sectional view showing the manufacturing process of the semiconductor device according to the first embodiment;

FIG. 11 is a cross-sectional view showing the manufacturing process of the semiconductor device according to the first embodiment;

FIG. 12 is a cross-sectional view showing the manufacturing process of the semiconductor device according to the first embodiment;

FIG. 13 is a cross-sectional view showing the manufacturing process of the semiconductor device according to the first embodiment;

FIG. 14 is a cross-sectional view showing the manufacturing process of the semiconductor device according to the first embodiment;

FIG. 15 is a cross-sectional view showing the manufacturing process of the semiconductor device according to the first embodiment;

FIG. 16 is a cross-sectional view showing the manufacturing process of the semiconductor device according to the first embodiment;

FIG. 17 is a cross-sectional view showing another manufacturing process of the semiconductor device according to the first embodiment;

FIG. 18 is a cross-sectional view showing the other manufacturing process of the semiconductor device according to the first embodiment;

FIG. 19 is a plan view showing a configuration of a semiconductor device according to a first comparison example;

FIG. 20 is a plan view showing a configuration of a semiconductor device according to a second comparison example;

FIG. 21 is a plan view showing the configuration of the semiconductor device according to the first embodiment;

FIG. 22 is a graph showing a relationship between the breakdown voltage and the specific on-resistance of the semiconductor devices according to the first and second comparison examples and the first embodiment;

FIG. 23 is a graph comparing the specific on-resistance when the semiconductor devices according to the first and second comparison examples and the first embodiment have substantially the same breakdown voltage;

FIG. 24 is a plan view showing a configuration of a semiconductor device according to a first application example of a second embodiment;

FIG. 25 is a plan view showing a configuration of a semiconductor device according to a second application example of the second embodiment;

FIG. 26 is a plan view showing a configuration of a semiconductor device according to a third application example of the second embodiment;

FIG. 27 is a plan view showing a configuration of a semiconductor device according to a fourth application example of the second embodiment;

FIG. 28 is a cross-sectional view showing a configuration of a semiconductor device according to a third embodiment;

FIG. 29 is a plan view showing the configuration of the semiconductor device according to the third embodiment;

FIG. 30 is a cross-sectional view showing a manufacturing process of the semiconductor device according to the third embodiment;

FIG. 31 is a cross-sectional view showing the manufacturing process of the semiconductor device according to the third embodiment;

FIG. 32 is a cross-sectional view showing the manufacturing process of the semiconductor device according to the third embodiment;

FIG. 33 is a cross-sectional view showing the manufacturing process of the semiconductor device according to the third embodiment;

FIG. 34 is a cross-sectional view showing the manufacturing process of the semiconductor device according to the third embodiment;

FIG. 35 is a cross-sectional view showing another manufacturing process of the semiconductor device according to the third embodiment;

FIG. 36 is a graph showing a relationship between the breakdown voltage and the specific on-resistance of the semiconductor devices according to the first and second comparison examples and the third embodiment;

FIG. 37 is a plan view showing a configuration of a semiconductor device according to a first modification example of a fourth embodiment;

FIG. 38 is a plan view showing a configuration of a semiconductor device according to a second modification example of the fourth embodiment;

FIG. 39 is a plan view showing a configuration of a semiconductor device according to a third modification example of the fourth embodiment;

FIG. 40 is a plan view showing a configuration of a semiconductor device according to a fourth modification example of the fourth embodiment;

FIG. 41 is a plan view showing a configuration of a semiconductor device according to a fifth modification example of the fourth embodiment;

FIG. 42 is a plan view showing a configuration of a semiconductor device according to a sixth modification example of the fourth embodiment;

FIG. 43 is a plan view showing a configuration of a semiconductor device according to a seventh modification example of the fourth embodiment; and

FIG. 44 is a plan view showing a configuration of a semiconductor device according to an eighth modification example of the fourth embodiment.

### DETAILED DESCRIPTION

In the following embodiments, although explanation is given with respect to each section or each embodiment as needed for convenience, the sections or embodiments are not irrelevant to each other but one may be a part or all of a modification example, application example, detailed description, or supplementary explanation of another, unless otherwise specified. Moreover, in the following embodiments, when a number (including number of pieces, numerical value, amount, range and the like) of an element is referenced, it is not limited to the specific number but may be more or less than the specific number, unless otherwise specified or explicitly limited to the specific number in principle.

Furthermore, in the following embodiments, components (including element steps) are not necessarily essential unless otherwise specified or explicitly essential in principle. Similarly, in the following embodiments, when a shape, positional relationship, or the like of the component is referenced, it includes substantially approximate or similar shape or the like unless otherwise specified or explicitly inapplicable in principle. This also applies to the number or the like (including number of pieces, numerical value, amount, range and the like).

Embodiments of the invention will be described below in detail with reference to drawings. It is to be noted that like or relevant reference numerals designate parts having like functions throughout the figures for illustrating the embodiments and the description thereof is not repeated. Moreover, in a case where a plurality of similar components (sites) are present, a symbol may be added to the collective reference numeral to indicate an individual or specific portion. Furthermore, in the following embodiments, the description of the same or similar portion is not repeated in principle unless specifically required.

Moreover, in the drawings used in the embodiments, hatching may be sometimes omitted for better visualization even in a cross-sectional view. Furthermore, hatching may be added for better visualization even in a plan view.

Moreover, in a cross-sectional view and a plan view, the size of each portion may not correspond to that of the actual device and a specific portion may be relatively enlarged for better visualization of the drawing. Furthermore, even when the cross-sectional view and the plan view are corresponding to each other, a specific portion may be relatively enlarged for better visualization of the drawing.

### First Embodiment

### [Description of Structure]

Hereinbelow, detailed explanation is given about a semiconductor device according to a first embodiment with reference to drawings.

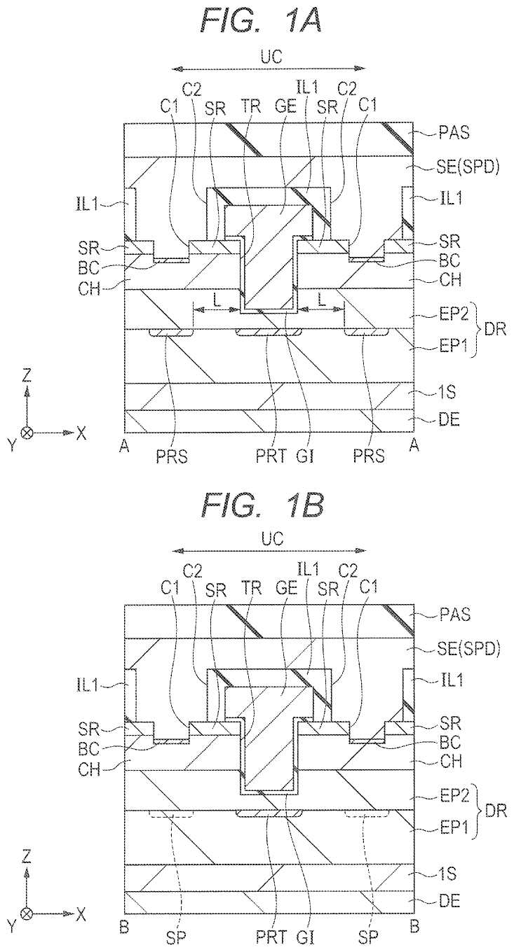

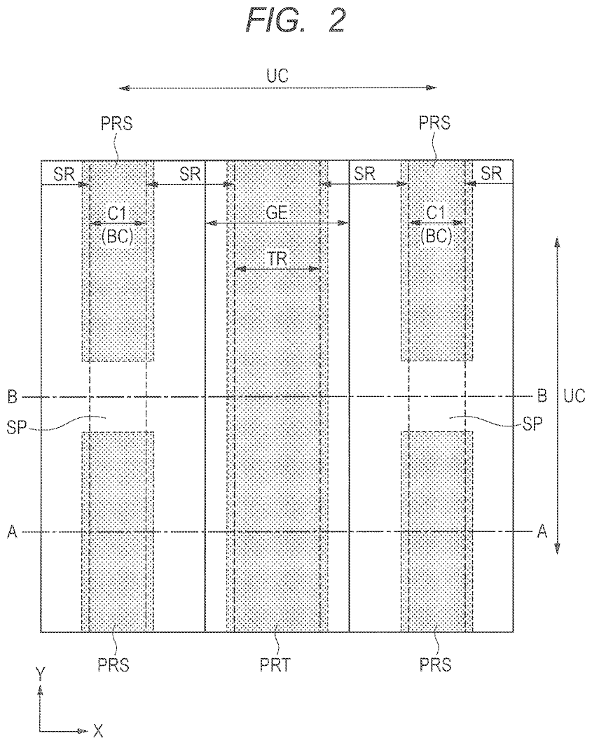

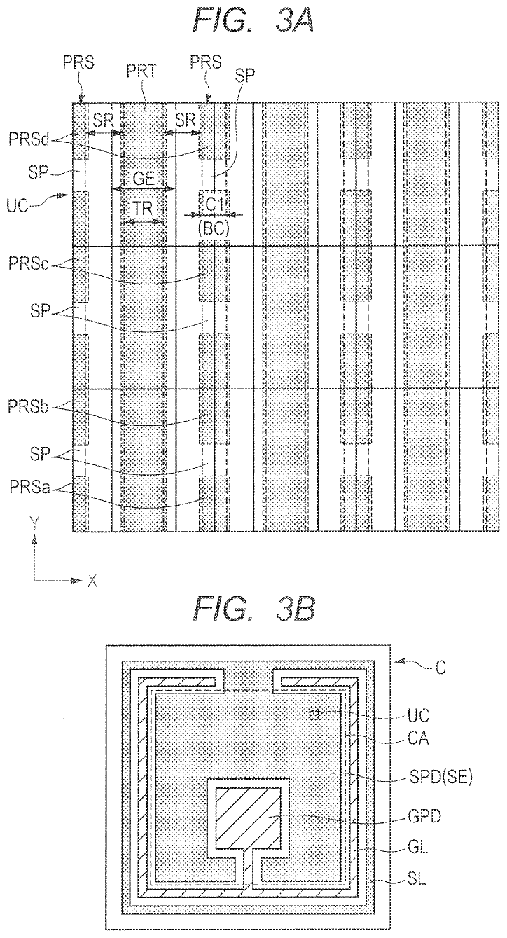

FIGS. 1A and 1B are cross-sectional views showing a configuration of the semiconductor device according to the first embodiment. FIGS. 2 and 3 are plan views showing the configuration of the semiconductor device according to the embodiment. The semiconductor device shown in FIGS. 1A, 1B, and the like is a trench gate power transistor.

As shown in FIG. 1A, the semiconductor device according to the embodiment includes a drift layer (drain region) DR arranged on a front face (first face) side of a SiC substrate 1S, a channel layer CH arranged over the drift layer DR, and a source region SR arranged over the channel layer CH. The drift layer DR includes an n-type semiconductor region, the channel layer CH includes a p-type semiconductor region, and the source region SR includes the n-type semiconductor region. These semiconductor regions include SiC, in which the p-type semiconductor region includes a p-type impurity and the n-type semiconductor region includes an n-type impurity. Moreover, the semiconductor regions can include either n-type or p-type epitaxial layer, as described later.

The semiconductor device according to the embodiment includes a gate electrode GE arranged via a gate insulating film GI in a trench TR penetrating the source region SR and the channel layer CH to reach the drift layer DR.

Arranged at an end opposite from the other end of the source region SR in contact with the trench TR are contact holes (C1, C2) reaching the channel layer CH. Here, as for the contact holes (C1, C2), in some cases, one with a larger width may be referred to as a contact hole C2 and one with a smaller width may be referred to as a contact hole C1. Formed over the bottom face of the contact holes (C1, C2) is a body contact region BC. The body contact region BC includes a p-type semiconductor region with impurity concentration higher than that of the channel layer CH, and it is formed to ensure ohmic contact between a source electrode SE and the channel layer CH.

Moreover, an interlayer insulating film IL1 is formed over the gate electrode GE. The interlayer insulating film IL1 includes an insulating film such as a silicon oxide film. The source electrode SE is arranged over the interlayer insulating film IL1 and inside the contact holes (C1, C2). The source electrode SE is configured by a conductive film. It is to be noted that, in some cases, a portion of the source electrode SE located inside the contact holes (C1, C2) may be regarded as a plug (via) and a portion thereof extending over the interlayer insulating film IL1 may be regarded to as a wiring. The source electrode SE is electrically coupled to the body contact region BC and the source region SR. Formed over the source electrode SE is a passivation film PAS configured by the insulating film. It is to be noted that a drain electrode DE is formed on a rear face (second face) side of the SiC substrate 1S.

In this embodiment, the drift layer DR includes a stack of a first drift epitaxial layer EP1 and a second drift epitaxial layer EP2 formed thereover, and p-type semiconductor regions (PRS, PRT) serving as buried layers are arranged at a boundary between the first drift epitaxial layer EP1 and the second drift epitaxial layer EP2. The p-type semiconductor regions (PRS, PRT, electric field relaxing layer) are arranged at a location deeper than the bottom face of the trench TR, include an impurity of a conductivity type opposite from that of the drift layer DR, and are located in the middle of the drift layer DR. Thus, providing the p-type semiconductor regions (PRS, PRT) makes it possible to increase the breakdown voltage of the gate insulating film GI.

As shown in FIG. 1A, among the p-type semiconductor regions (PRS, PRT) at the boundary between the first drift epitaxial layer EP1 and the second drift epitaxial layer EP2, the p-type semiconductor region located below the trench TR is designated by “PRT” and the p-type semiconductor region located below the body contact region BC (i.e. next to the trench TR) is designated by “PRS”.

The p-type semiconductor region PRT is formed in the drift layer DR below the trench TR in a position overlapping the region where the trench is formed as seen from above, and includes the impurity of the conductivity type opposite from that of the drift layer DR. Moreover, the p-type semiconductor region PRS is formed at a distance L from the region where the trench is formed as seen from above in the drift layer DR below the trench TR, and includes the impurity of the conductivity type opposite from that of the drift layer DR.

Furthermore, as described later, the p-type semiconductor region PRS is configured by a plurality of regions (PRSa to PRSd) arranged at a predetermined space (SP) along the trench TR. In other words, the p-type semiconductor region PRS is arranged in the extending direction of the trench TR (gate electrode GE) with a portion thereof being thinned out. The region where the p-type semiconductor region PRS is thinned out becomes the space SP, and a region between the spaces SP becomes a remaining individual region (individual semiconductor regions PRSa to PRSd) (see FIGS. 2 and 3).

In this manner, by thinning out the p-type semiconductor region PRS, it is possible to ensure an electric current path (electric current path) and to reduce the specific on-resistance.

The transistor shown in FIG. 1 is, as described later, arranged in a repeated manner as seen from above (see FIGS. 2 and 3). Thus, the transistor shown in FIG. 1 may be referred to as a “unit transistor (unit cell) UC”. The “unit transistor (unit cell) UC” is the minimum unit of repetition.

FIGS. 2, 3A, and 3B are plan views showing the configuration of the semiconductor device according to the embodiment, where FIG. 1A corresponds to the cross-sectional view along a line A-A in FIG. 2 and FIG. 1B corresponds to the cross-sectional view along a line B-B in FIG. 2, for example. Moreover, the region UC shown in FIG. 2 corresponds to the region UC shown in FIG. 3B. In a cell region CA shown in FIG. 3B, unit transistors (unit cells) UC are arranged in an array. FIG. 3B shows a single chip region. FIG. 3A corresponds to 3*3=9 regions UC.

As shown in FIG. 2, a plane shape of the gate electrode GE is rectangular having a longitudinal side in a Y direction. The plane shape of the trench TR is rectangular having a longitudinal side in the Y direction. Arranged on both sides of the trench TR are source regions SR. The plane shape of the source region SR is rectangular having a longitudinal side in the Y direction. Arranged outside the source region SR is the body contact region BC. The plane shape of the body contact region BC is rectangular having a longitudinal side in the Y direction.

The unit transistors UC are arranged in an X direction and the Y direction in a repeated manner, as shown in FIG. 3A.

As shown in FIGS. 1 and 3B, the source electrode SE expands to extend over the gate electrode GE. Although not shown in the cross-sectional views of FIG. 1, a gate line GL and a gate pad GPD shown in FIG. 3B are arranged over the end of the gate electrode GE via an unshown contact hole (plug, via). The gate line GL and the gate pad GPD can be configured by a conductive film in the same layer as the source electrode SE.

As described above, the p-type semiconductor regions (PRS, PRT) extend in the Y direction (in the depth direction in FIG. 1) like the trench TR and the gate electrode GE. Moreover, as shown in FIG. 3A, the p-type semiconductor region PRS is configured by a plurality of regions (PRSa to PRSd) arranged at a predetermined space (SP) in the Y direction. It is to be noted that FIG. 1B corresponds to a cross-section of the above-mentioned space SP.

### <Operation>

In the semiconductor device (transistor) according to the embodiment, when a gate voltage equal to or higher than a threshold voltage is applied to the gate electrode GE, an inversion layer (n-type semiconductor region) is formed in a channel layer (p-type semiconductor region) CH in contact with a side face of the trench TR. The source region SR and the drift layer DR are now electrically coupled by the inversion layer, where an electron is transferred from the source region SR to the drift layer DR via the inversion layer, when there is a potential difference between the source region SR and the drift layer DR. In other words, an electric current flows from the drift layer DR to the source region SR through the inversion layer. The transistor can be turned on in this manner.

On the other hand, when a voltage lower than the threshold voltage is applied to the gate electrode GE, the inversion layer formed in the channel layer CH is lost and the source region SR and the drift layer DR are electrically decoupled from each other. The transistor can be turned off in this manner.

As described above, by changing the gate voltage applied to the gate electrode GE of the transistor, the transistor is turned on/off.

### [Description of Manufacturing Method]

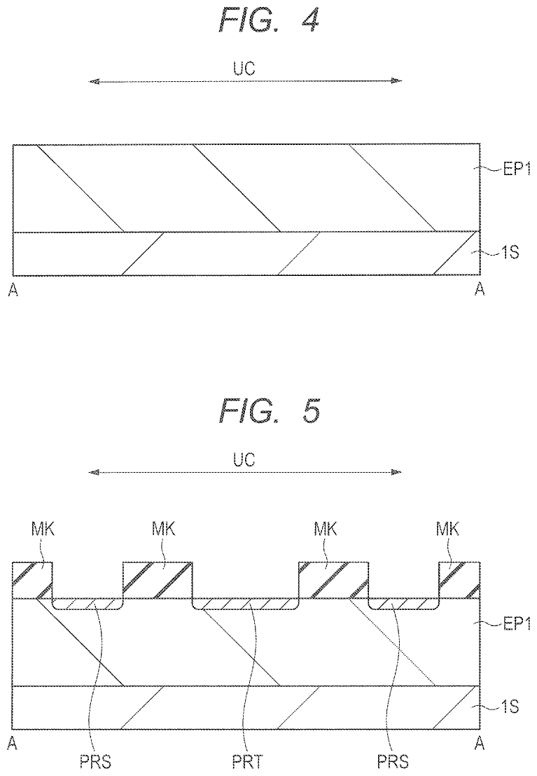

Next, with reference to FIGS. 4 to 16, a method of manufacturing the semiconductor device according to the embodiment is described and the configuration of the semiconductor device is more clearly expressed. FIGS. 4 to 16 are cross-sectional views and plan views showing a manufacturing process of the semiconductor device according to the embodiment.

First, as shown in FIG. 4, a SiC substrate (semiconductor substrate or wafer configured by SiC) having a first drift epitaxial layer EP formed thereon is provided.

There is no limitation to the method of forming the epitaxial layer over the SiC substrate 1S, and it can be formed in the following manner as an example. For example, the first drift epitaxial layer EP1 is formed by growing an epitaxial layer (n-type epitaxial layer) including SiC while introducing an n-type impurity such as nitrogen (N) and phosphorus (P) over the SiC substrate 1S.

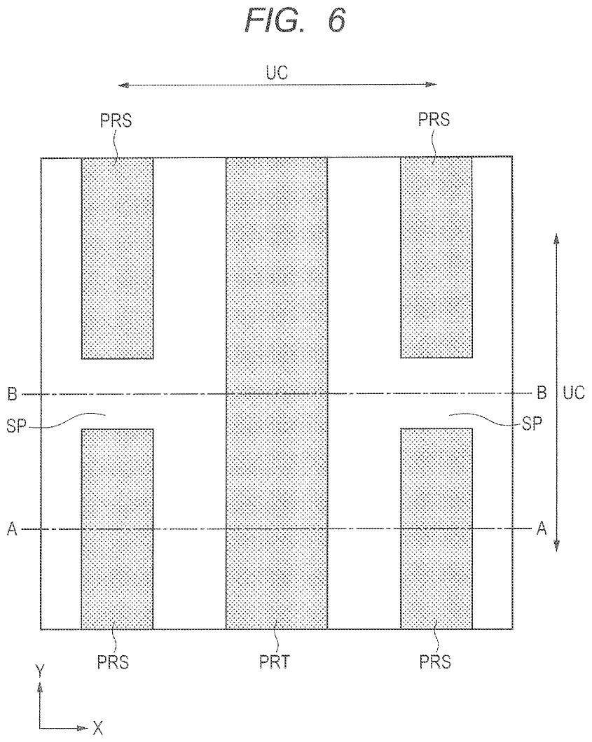

Next, as shown in FIGS. 5 and 6, the p-type semiconductor regions (PRS, PRT) are formed. For example, a mask film MK having an opening in a region where the p-type semiconductor regions (PRS, PRT) are formed is formed over the first drift epitaxial layer EP1 using a photolithography technique and an etching technique. A silicon oxide film may be used as the mask film MK, for example.

The p-type semiconductor regions (PRS, PRT) are formed over a surface of the first drift epitaxial layer EP1 by ion-implanting the p-type impurity such as aluminum (Al) or boron (B) using the mask film MK as a mask.

As shown in FIG. 6, the p-type semiconductor regions (PRS, PRT) extend in the Y direction and the p-type semiconductor region PRS is spaced by the space SP in the Y direction. In other words, the unit cell UC is provided with the space SP at the center of the p-type semiconductor region PRS in the Y direction.

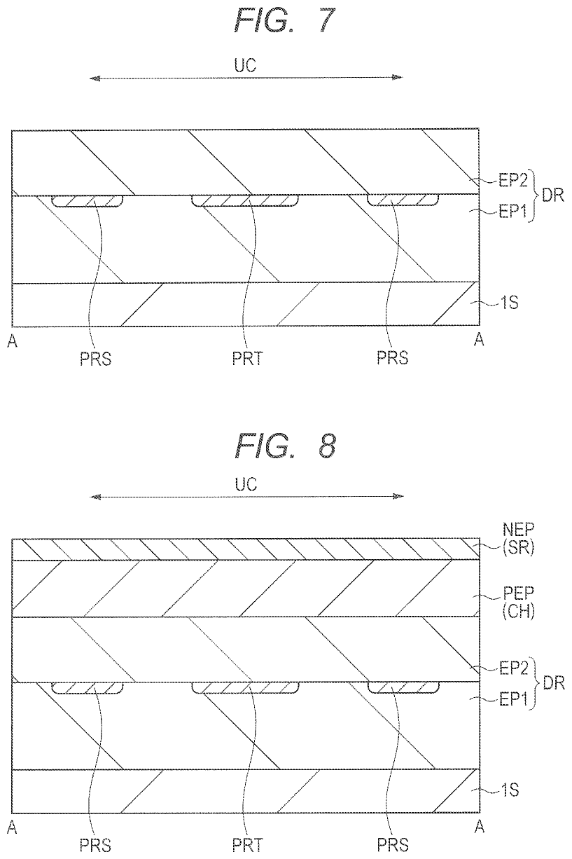

The second drift epitaxial layer EP2 is then formed as shown in FIG. 7. For example, the second drift epitaxial layer EP2 is formed by growing the epitaxial layer (n-type epitaxial layer) including SiC while introducing the n-type impurity such as nitrogen (N) and phosphorus (P) over the first drift epitaxial layer EP1 and the p-type semiconductor regions (PRS, PRT). This allows for forming the drift layer DR configured by the stack of the first drift epitaxial layer EP1 and the second drift epitaxial layer EP2. Moreover, the p-type semiconductor regions (PRS, PRT) are to be arranged inside the drift layer DR. Specifically, the p-type semiconductor regions (PRS, PRT) are arranged near the boundary between the first drift epitaxial layer EP1 and the second drift epitaxial layer EP2.

Subsequently, as shown in FIG. 8, a p-type epitaxial layer PEP serving as the channel layer CH and an n-type epitaxial layer NEP serving as the source region SR are formed. For example, the p-type epitaxial layer (channel layer CH) PEP is formed by growing an epitaxial layer (p-type epitaxial layer) including SiC while introducing a p-type impurity over the drift layer DR, and then the n-type epitaxial layer (source region SR) NEP is formed by growing the epitaxial layer (n-type epitaxial layer) including SiC while introducing the n-type impurity. It is to be noted that the semiconductor region corresponding to the n-type epitaxial layer NEP and the p-type epitaxial layer PEP may be formed by ion implantation.

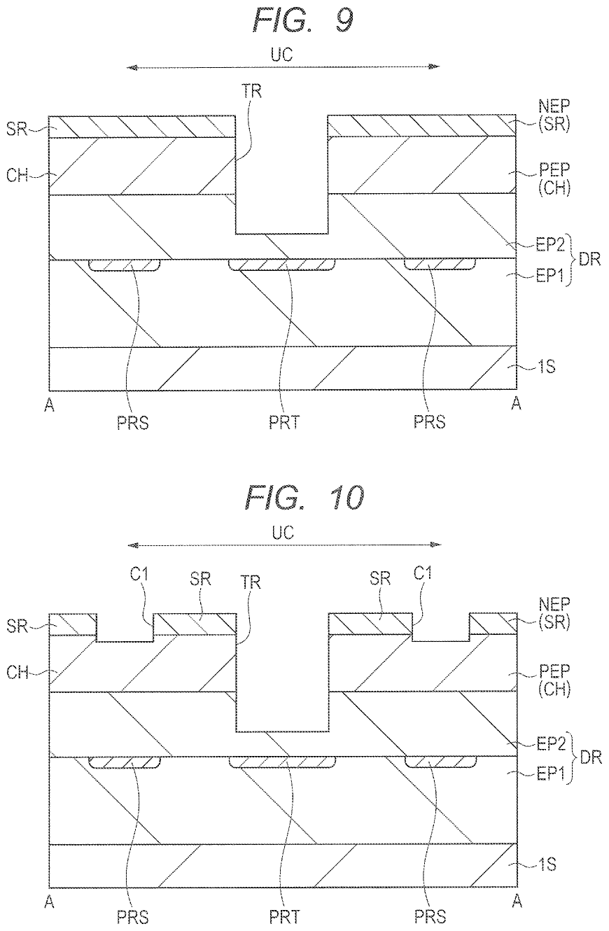

Then, as shown in FIG. 9, the trench TR is formed that penetrates the n-type epitaxial layer (source region SR) NEP and the p-type epitaxial layer (channel layer CH) PEP to reach the second drift epitaxial layer EP2.

For example, a hard mask (not shown) having an opening in the region where the trench TR is formed is formed over the n-type epitaxial layer (source region SR) NEP using the photolithography technique and the etching technique. Next, the trench TR is formed by etching top of the n-type epitaxial layer (source region SR) NEP, the p-type epitaxial layer (channel layer CH) PEP, and the second drift epitaxial layer EP2 using the hard mask (not shown) as a mask. The hard mask (not shown) is then removed. The second drift epitaxial layer EP2, the p-type epitaxial layer (channel layer CH) PEP, and the n-type epitaxial layer (source region SR) NEP are exposed in this order on the side face of the trench TR. Furthermore, the second drift epitaxial layer EP2 is exposed on the bottom face of the trench TR. Here, the p-type semiconductor regions (PRS, PRT) is arranged at a location deeper than the bottom face of the trench TR.

Next, as shown in FIG. 10, a contact hole C1 is formed in each of the n-type epitaxial layers (source regions SR) NEP on both sides of the trench TR.

For example, the hard mask (not shown) having the opening in the region where the contact hole C1 is formed is formed over the n-type epitaxial layer (source region SR) NEP using the photolithography technique and the etching technique. Then, the contact hole C1 is formed by etching the top of the n-type epitaxial layer (source region SR) NEP and the p-type epitaxial layer (channel layer CH) PEP using the hard mask (not shown) as the mask. The p-type epitaxial layer (channel layer CH) PEP is exposed on the bottom face of the contact hole C1.

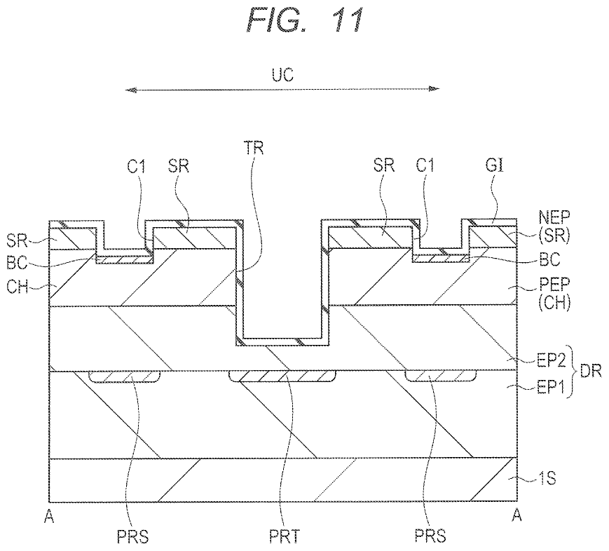

Subsequently, as shown in FIG. 11, the body contact region BC is formed below the bottom face of the contact hole C1 and the gate insulating film GI is formed over the n-type epitaxial layer (source region SR) NEP including the inside of the trench TR and the contact hole C1.

For example, the body contact region BC is formed by ion-implanting the p-type impurity into the p-type epitaxial layer PEP (channel layer CH) exposed on the bottom face of the contact hole C1 using the above-mentioned hard mask (not shown) as the mask. The concentration of the p-type impurity in the body contact region BC is higher than that of the p-type impurity in the p-type epitaxial layer PEP (channel layer CH). The hard mask (not shown) is then removed.

Next, the silicon oxide film is formed as the gate insulating film GI over the n-type epitaxial layer (source region SR) NEP including the inside of the trench TR and the contact hole C1, for example, by the ALD (Atomic Layer Deposition) method or the like. The gate insulating film GI may also be formed by thermally oxidizing the epitaxial layer exposed inside the trench TR. Besides the silicon oxide film, a high-dielectric-constant film having a higher dielectric constant than that of the silicon oxide film, such as an aluminum oxide film or a hafnium oxide film, may be used as the gate insulating film GI.

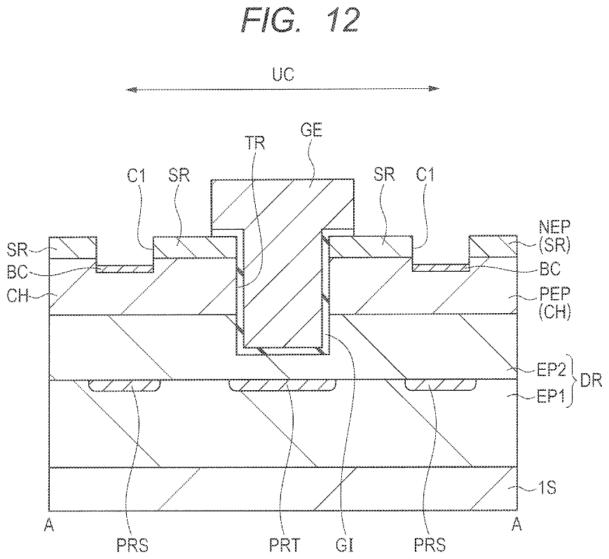

Then, as shown in FIG. 12, the gate electrode GE is formed that is arranged over the gate insulating film GI and that is shaped to fill the trench TR. For example, a polycrystalline silicon film is deposited by the CVD (Chemical Vapor Deposition) method as the conductive film for the gate electrode GE. A photoresist film (not shown) covering the region where the gate electrode GE is formed is then formed over the conductive film, and the conductive film is etched using the photoresist film as the mask. This allows for forming the gate electrode GE. During the etching, the gate insulating film GI exposed on both sides of the gate electrode GE may be etched.

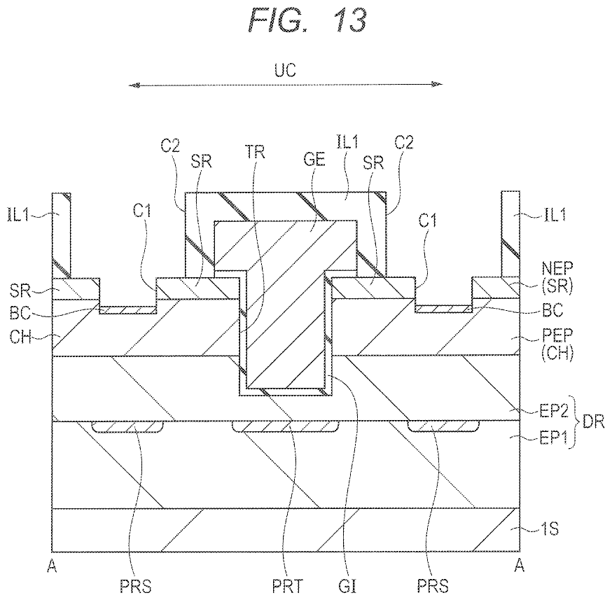

Next, as shown in FIG. 13, the interlayer insulating film IL1 covering the gate electrode GE is formed, and the contact hole C2 is formed.

For example, the silicon oxide film is deposited by the CVD method as the interlayer insulating film IL1 over the body contact region BC, the n-type epitaxial layer (source region SR) NEP, and the gate electrode GE exposed on the bottom face of the contact hole C1. The photoresist film (not shown) having an opening on the body contact region BC and a portion of the source region SR on both sides thereof is then formed over the interlayer insulating film IL1. Next, the contact hole C2 is formed by etching the interlayer insulating film IL1 using the photoresist film as the mask. The contact hole C1 is located below the contact hole C2. The body contact region BC and a portion of the source region SR on both sides thereof are exposed below the contact holes (C1, C2). It is to be noted that the interlayer insulating film IL1 over the gate electrode GE not shown in the cross-sectional view of FIG. 13 is removed, and the contact hole (not shown) is also formed over the gate electrode GE.

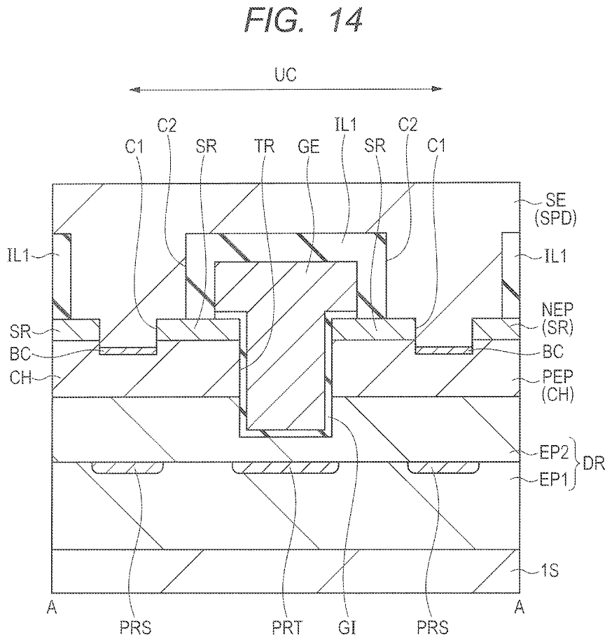

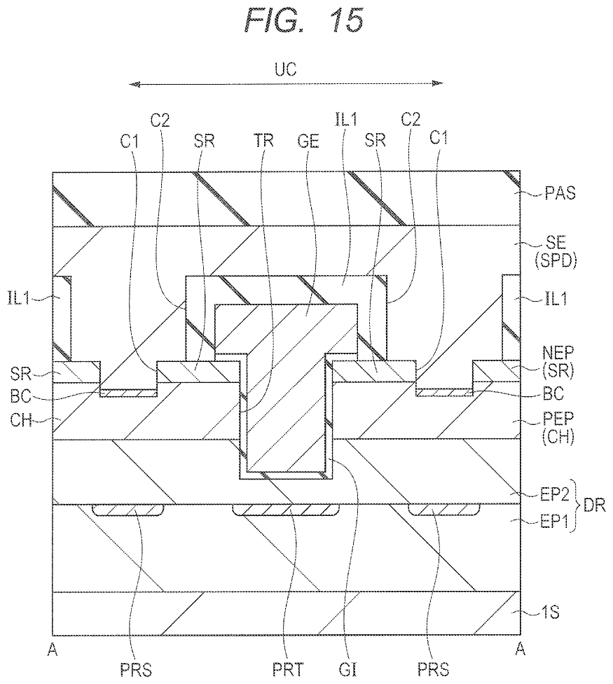

Subsequently, as shown in FIG. 14, the source electrode SE is formed. For example, a TiN film is formed by the sputtering method or the like as a barrier metal film (not shown) inside the contact holes (C1, C2) and over the interlayer insulating film IL1. An Al film is then formed over the barrier metal film (not shown) as the conductive film by the sputtering method or the like. The source electrode SE is then formed by patterning a lamination of the barrier metal film (not shown) and the conductive film (Al film). In doing so, the gate line GL and the gate pad GPD not appearing in the cross-sectional view of FIG. 14 are formed (see FIG. 3B). It is to be noted that the source electrode SE or the like may be formed over the body contact region BC (inner wall of the contact hole C1) after forming a silicide film.

Next, as shown in FIG. 15, the passivation film PAS is formed so as to cover the source electrode SE, the gate line GL, and the gate pad GPD. For example, the silicon oxide film is deposited as the passivation film PAS over the source electrode SE or the like using the CVD method or the like. a partial region of the source electrode SE and a partial region of the gate pad GPD are then exposed by patterning the passivation film PAS. These exposed portions become externally coupling regions (pads).

Subsequently, setting the rear face (second face) opposite from a main face of the SiC substrate 1S as the top face, the rear face of the SiC substrate 1S is ground for thinning the SiC substrate 1S.

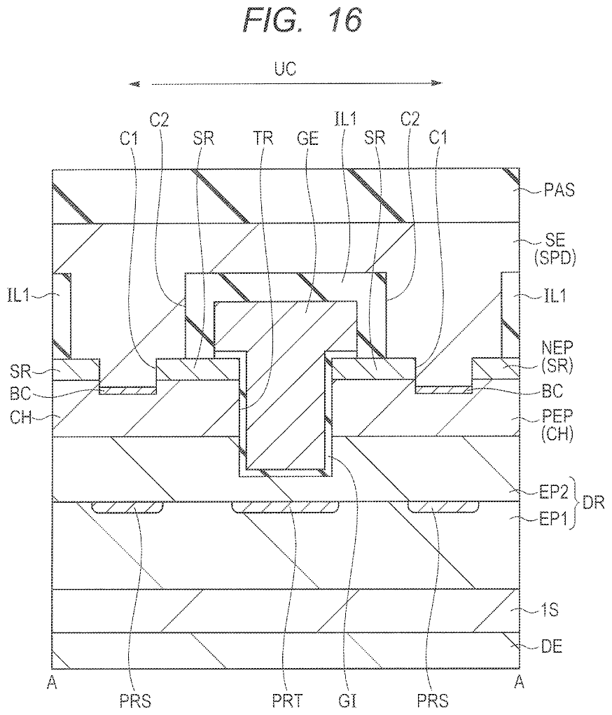

Next, as shown in FIG. 16, the drain electrode DE is formed over the rear face of the SiC substrate 1S. For example, a metal film is formed setting the rear face side of the SiC substrate 1S as the top face. For example, a Ti film, an Ni film, and an Au film are sequentially formed by the sputtering method. This allows for forming the drain electrode DE configured by the metal film. It is to be noted that the silicide film may be formed between the metal film and the SiC substrate 1S. After this, the SiC substrate (wafer) 1S having a plurality of chip regions is diced each chip region.

In the above-described process, the semiconductor device according to the embodiment can be formed.

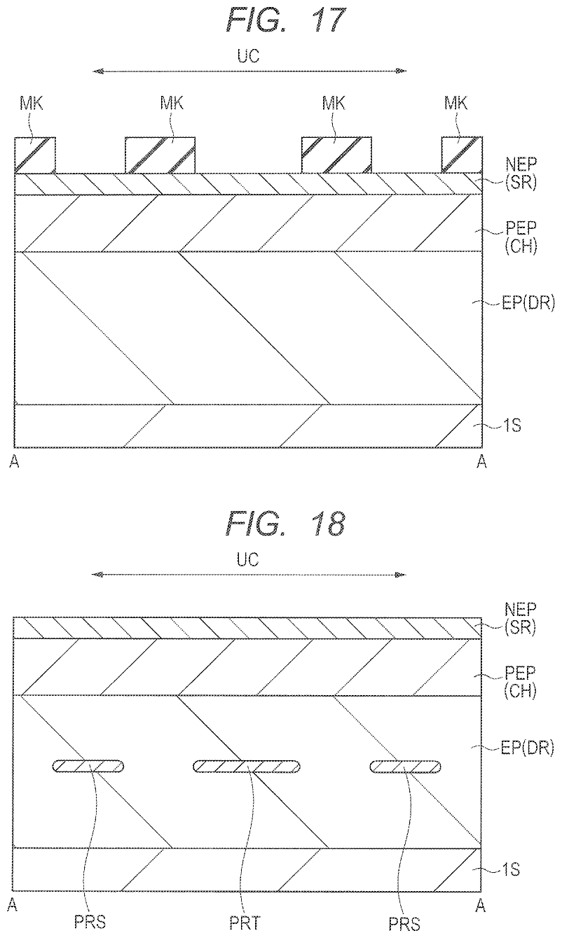

It is to be noted that, although the drift layer DR is configured by the lamination of the first drift epitaxial layer EP1 and the second drift epitaxial layer EP2 in the above-mentioned process, the drift layer DR may be a single epitaxial layer EP and the p-type semiconductor regions (PRS, PRT) may be provided therein by deep ion implantation, as shown in FIGS. 17 and 18. FIGS. 17 and 18 are cross-sectional views showing another manufacturing process of the semiconductor device according to the embodiment.

As described above, according to the embodiment, it is possible to reduce the specific on-resistance while maintaining the breakdown voltage of the gate insulating film GI by providing the p-type semiconductor regions (PRS, PRT) and further by arranging the p-type semiconductor region PRS spaced by the space SP in the Y direction. As used herein, “specific on-resistance” is a resistance calculated from a current and a voltage multiplied by a device area.

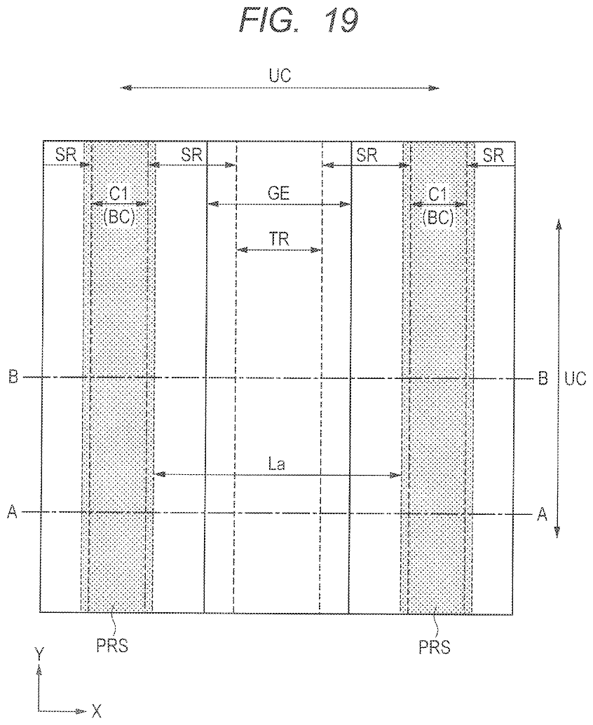

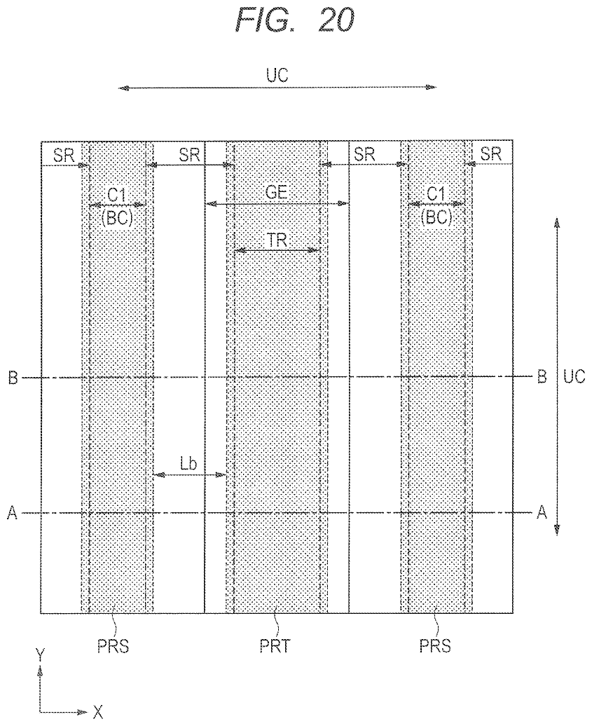

FIG. 19 is a plan view showing a configuration of a semiconductor device according to a first comparison example. FIG. 20 is a plan view showing a configuration of a semiconductor device according to a second comparison example. It is to be noted that, in the first and second comparison examples, the configurations are the same as that of the first embodiment (FIGS. 1 and 2) except the region where the p-type semiconductor region (PRS or PRT) is formed. Accordingly, for the configurations of the first and second comparison examples, only the portions different from the first embodiment (FIGS. 1 and 2) are described in detail.

In the first comparison example, as shown in FIG. 19, the p-type semiconductor region PRT is not arranged below the trench TR and the p-type semiconductor region PRS is arranged below the body contact region BC. The p-type semiconductor region PRS is provided linearly extending in the Y direction without the space SP.

In the second comparison example, as shown in FIG. 20, the p-type semiconductor region PRT is arranged below the trench TR, and the p-type semiconductor region PRS is further arranged below the body contact region BC. Each of the p-type semiconductor regions PRT, PRS is provided linearly extending in the Y direction without the space SP.

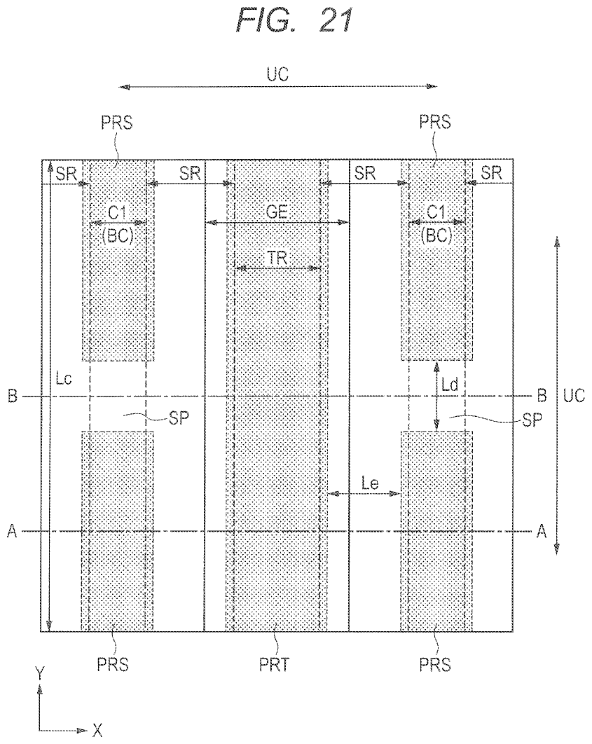

To the contrary, in the embodiment (FIGS. 1 and 2), as shown in FIG. 21, the p-type semiconductor region PRT is arranged below the trench TR and the p-type semiconductor region PRS is further arranged below the body contact region BC. Furthermore, the p-type semiconductor region PRS is spaced by the space SP in the Y direction.

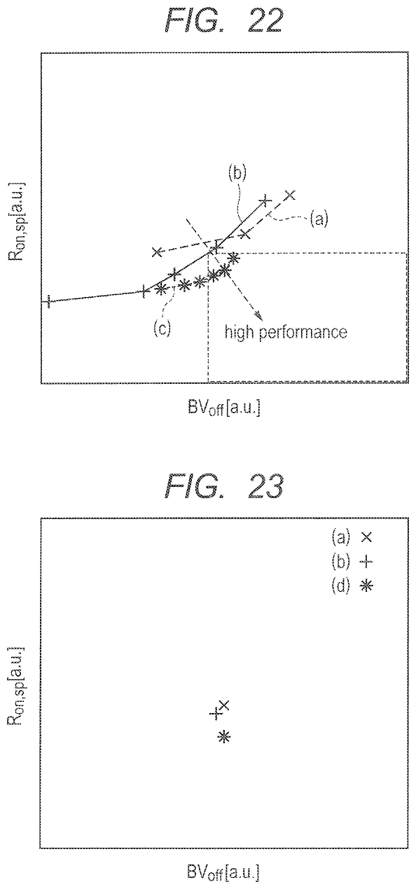

FIG. 22 is a graph showing a relationship between the breakdown voltage and the specific on-resistance of the semiconductor devices according to the first and second comparison examples and the first embodiment. The abscissa indicates the breakdown voltage (BV_{off}, [a.u.]), and the ordinate indicates the specific on-resistance R_{on,sp}, [a.u.]). A curve (a) indicates the second comparison example, a curve (b) indicates the first comparison example, and a curve (c) indicates the present embodiment. As an example of the embodiment, a length of the p-type semiconductor region PRT in the Y direction (Lc) is assumed as 1.6 to 2.0 μm and a length of the space SP in the Y direction (Ld) is assumed as 0.3 to 0.5 μm. Furthermore, a space between the p-type semiconductor region PRT and the p-type semiconductor region PRS is assumed as 1.0 to 1.4 μm and concentrations of the p-type impurity in the p-type semiconductor region PRT and the p-type semiconductor region PRS are assumed as 2×10¹⁸ to 7×10¹⁸ cm⁻³. Moreover, as an example of the first comparison example, a space between the p-type semiconductor regions PRS (La) is assumed as 2.0 to 2.6 μm and a space between the p-type semiconductor region PRT and the p-type semiconductor region PRS (Lb) is assumed as 1.0 to 1.4 μm.

As shown in FIG. 22, performance increases (high performance) towards a bottom right region of the graph, i.e. in a direction of an arrow in the drawing. In other words, for example, in the region surrounded by a broken line, the breakdown voltage is high and the on-resistance is low. As can be seen from FIG. 22, in the first comparison example (curve (b)) and the second comparison example (curve (a)), it is not possible to achieve the high breakdown voltage and the low specific on-resistance in the region surrounded by the broken line no matter how the values are adjusted. To the contrary, in the embodiment (curve (c)), it is possible to achieve the high breakdown voltage and the low specific on-resistance in the region surrounded by the broken line. Moreover, it can be seen that the curve (c) tends to shift in the direction of the arrow in the drawing compared to the curves (a) and (b) and that the specific on-resistance can be reduced while maintaining the breakdown voltage in the embodiment.

FIG. 23 is a graph comparing the specific on-resistance when the semiconductor devices according to the first and second comparison examples and the present embodiment have substantially the same breakdown voltage.

In this manner, the semiconductor device according to the embodiment allows for reducing the specific on-resistance while maintaining the breakdown voltage.

### Second Embodiment

In this embodiment, application examples of the first embodiment are described.

### First Application Example

Although a portion of the p-type semiconductor region PRS is thinned out in the first embodiment (FIG. 2), it is also possible to thin out a portion of the p-type semiconductor region PRT. In other words, although the p-type semiconductor region PRS is spaced by the space SP in the Y direction in the first embodiment (FIG. 2), the p-type semiconductor region PRT may be spaced by the space SP in the Y direction.

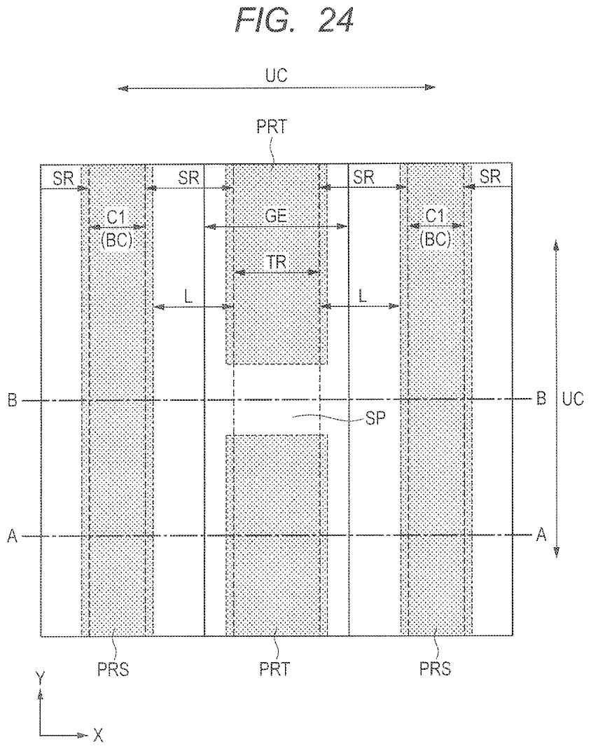

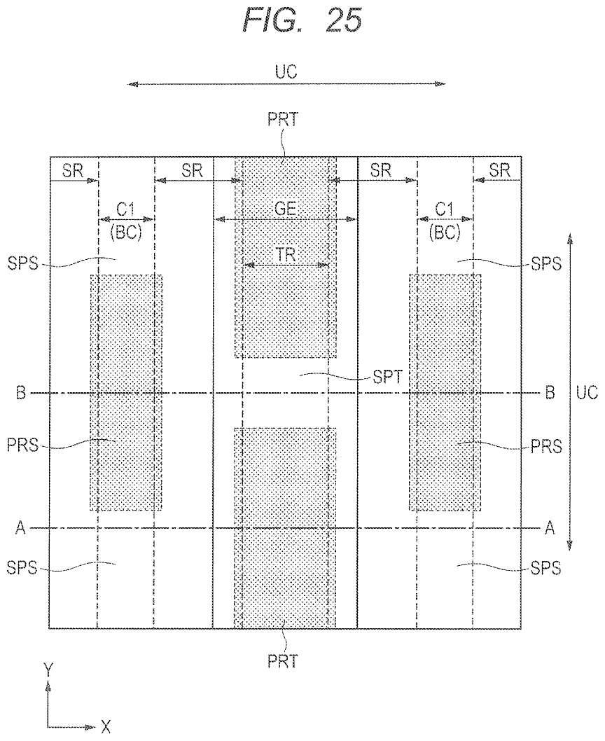

FIG. 24 is a plan view showing a configuration of a semiconductor device according to a first application example. The application example has the same configuration as the first embodiment (FIGS. 1, 2, and the like) except the region where the p-type semiconductor regions (PRS, PRT) are formed.

In this application example, the p-type semiconductor region PRT is formed in the drift layer DR below the trench TR in a position overlapping the region where the trench is formed as seen from above, and includes the impurity of the conductivity type opposite from that of the drift layer DR. Moreover, the p-type semiconductor region PRS is formed at the distance L from the region where the trench is formed as seen from above in the drift layer DR below the trench TR, and includes the impurity of the conductivity type opposite from that of the drift layer DR.

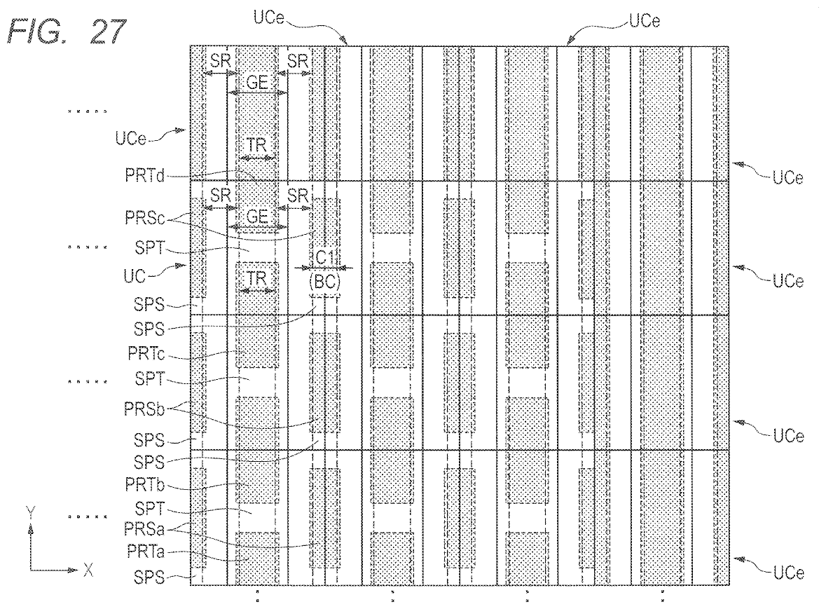

The p-type semiconductor region PRT is arranged at a predetermined space (SP) along the trench TR. In other words, the p-type semiconductor region PRT is arranged in the extending direction of the trench TR (gate electrode GE) with a portion thereof being thinned out. The region where the p-type semiconductor region PRT is thinned out becomes the space SP, and a region between the spaces SP becomes a remaining individual region (individual semiconductor regions PRTa to PRTd) (see FIG. 27).

Moreover, in other words, the unit cell UC is provided with the space SP at the center of the p-type semiconductor region PRT in the Y direction (FIG. 24).

### Second Application Example

Although the space SP is arranged in either one of the p-type semiconductor regions (PRS, PRT) in the first embodiment (FIG. 2) and the first application example (FIG. 24), spaces SPS, SPT may be provided to both of the p-type semiconductor regions (PRS, PRT). In this case, it is preferable to arrange the space SPS of the p-type semiconductor region PRS and the space SPT of the p-type semiconductor region PRT so as not to overlap in the Y direction.

FIG. 25 is a plan view showing a configuration of a semiconductor device according to a second application example. The application example has the same configuration as the first embodiment (FIGS. 1, 2, and the like) except the region where the p-type semiconductor regions (PRS, PRT) are formed.

In this application example, the p-type semiconductor region PRT is formed in the drift layer DR below the trench TR in a position overlapping the region where the trench is formed as seen from above, and includes the impurity of the conductivity type opposite from that of the drift layer DR. Moreover, the p-type semiconductor region PRS is formed at the distance L from the region where the trench is formed as seen from above in the drift layer DR below the trench TR, and includes the impurity of the conductivity type opposite from that of the drift layer DR.

The p-type semiconductor region PRS is configured by a plurality of regions (PRSa to PRSc) arranged at a predetermine space (SPS) along the trench TR. In other words, the p-type semiconductor region PRS is arranged in the extending direction of the trench TR (gate electrode GE) with a portion thereof being thinned out. The region where the p-type semiconductor region PRS is thinned out becomes the space SPS, and a region between the spaces SPS becomes a remaining individual region (individual semiconductor regions PRSa to PRSc) (see FIG. 27).

Moreover, the p-type semiconductor region PRT is configured by a plurality of regions (PRTa to PRTd) arranged at a predetermine space (SPT) along the trench TR. In other words, the p-type semiconductor region PRT is arranged in the extending direction of the trench TR (gate electrode GE) with a portion thereof being thinned out. The region where the p-type semiconductor region PRT is thinned out becomes the space SPT, and a region between the spaces SPT becomes a remaining individual region (individual semiconductor regions PRTa to PRTd) (see FIG. 27).

Moreover, in other words, the unit cell UC is provided with the space SPT at the center of the p-type semiconductor region PRT in the Y direction and the space SPS at both ends of the p-type semiconductor region PRS in the Y direction (FIG. 25).

In this manner, the p-type semiconductor region PRS is arranged at a position corresponding to the space SPT of the p-type semiconductor region PRT (such an arrangement may be referred to as “staggered arrangement”). In other words, the above-mentioned individual region (individual semiconductor regions PRSa to PRSc) is present at a position of the region where the p-type semiconductor region PRT is thinned out (space SPT) in the Y direction (FIG. 27). This makes it possible to prevent a high electric field from being applied locally to the gate insulating film (GI), thereby effectively increasing the breakdown voltage of the semiconductor device according to the embodiment.

### Third Application Example

Although the spaces SPS and SPT are arranged in both of the p-type semiconductor regions (PRS, PRT) and the p-type semiconductor regions (PRS, PRT) are subdivided in the second application example (FIG. 25), these regions (patterns) may be coupled by a coupling CR.

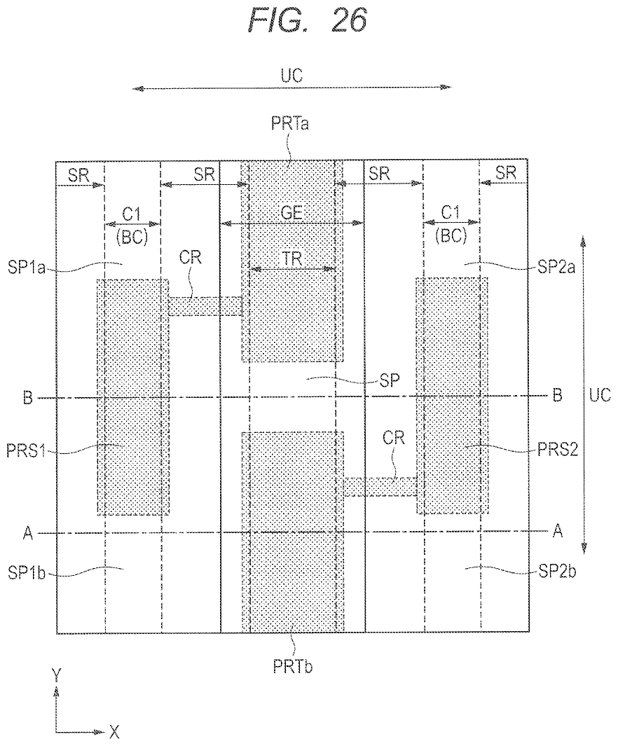

FIG. 26 is a plan view showing a configuration of a semiconductor device according to a third application example. In the application example, the configuration is the same as that of the first embodiment (FIGS. 1 and 2) except the p-type semiconductor regions (PRS, PRT) and the coupling CR.

The unit cell UC of the application example is provided with the space SP at the center of the p-type semiconductor region PRT in the Y direction. In other words, the p-type semiconductor region PRT includes a first portion PRTa and a second portion PRTb in the unit cell UC. A region between the first portion PRTa and the second portion PRTb is the space SP.

In the unit cell UC according to the application example, both the p-type semiconductor regions PRS1 and PRS2 extend in the Y direction, and spaces SP1a, SP1b, SP2a, and SP2b are arranged at both ends of the p-type semiconductor regions PRS1 and PRS2 in the Y direction in FIG. 25.

Specifically, the p-type semiconductor region PRS1 is arranged at the center of the unit cell UC in the Y direction in FIG. 26 and includes the first space SP1a and the second space SP1b at both ends thereof. Moreover, the p-type semiconductor region PRS2 is arranged at the center of the unit cell UC in the Y direction in FIG. 26 and includes the first space SP2a and the second space SP2b at both ends thereof.

The p-type semiconductor region PRS1 and the first portion PRTa are coupled by the coupling (semiconductor region) CR extending in the X direction, and the p-type semiconductor region PRS2 and the second portion PRTb are coupled by the coupling CR extending in the X direction. These couplings are configured by the p-type semiconductor region.

In this manner, it is possible to prevent the potential in each region (each pattern) from being unstable by electrically coupling these patterns (p-type semiconductor regions PRS1, PRS2, first portion PRTa, second portion PRTb).

Especially by fixing the regions (patterns) to a predetermined potential such as the ground potential (GND) while electrically coupling them, it is possible to suppress potential variation of the regions (patterns) and to improve stability during dynamic operation.

It is also possible to reduce the specific on-resistance while maintaining the breakdown voltage of the gate insulating film GI in the above-mentioned first to third application examples, as detailed in the first embodiment.

It is to be noted that the semiconductor devices according to the first to third application examples can be formed in the same manner as the first embodiment except that the region where the impurity is implanted when forming the p-type semiconductor regions (PRS, PRT) is different.

### Fourth Application Example

According to a fourth application example, the unit cell in the outermost periphery of the cell region (CA) does not include the space SP in the p-type semiconductor regions (PRS, PRT).

FIG. 27 is a plan view showing a configuration of a semiconductor device according to the application example. In this application example, the configuration is the same as that of the above-mentioned second application example (FIG. 25) expect the unit cell UCe in the outermost periphery of the cell region (CA).

As shown in FIG. 27, in the unit cell UCe in the outermost periphery of the cell region (CA), the p-type semiconductor regions (PRS, PRT) are formed linearly extending in the Y direction.

As described above, it is preferable for the unit cell UCe in the outermost periphery to maintain high breakdown voltage and there is little contribution to on-state current. Therefore, it is possible to maintain the high breakdown voltage while suppressing reduction of the on-state current by providing no space (SPS, SPT).

It is to be noted that the semiconductor device according to this application example can be formed in the same manner as the first embodiment except that the region where the impurity is implanted when forming the p-type semiconductor regions (PRS, PRT) is different.

Moreover, although the unit cell UC arranged inside the cell region (CA) is the same one as in the above-mentioned second application example (FIG. 25), it may be alternatively the same one as in the first embodiment (FIG. 2), the first application example (FIG. 24), or the third application example (FIG. 26).

### Third Embodiment

According to a third embodiment, the p-type semiconductor regions (PRS, PRT) are formed at different heights. Such a configuration allows for maintaining the breakdown voltage of the gate insulating film GI and reducing the specific on-resistance.

### [Description of Structure]

A semiconductor device according to this embodiment is described below in detail with reference to drawings. It is to be noted that the configuration of the semiconductor device according to this embodiment is the same as that of the first embodiment except the drift layer (including the p-type semiconductor regions (PRS, PRT)) DR, and therefore parts corresponding to those in the first embodiment are given the same reference numerals and detailed description thereof is not repeated herein.

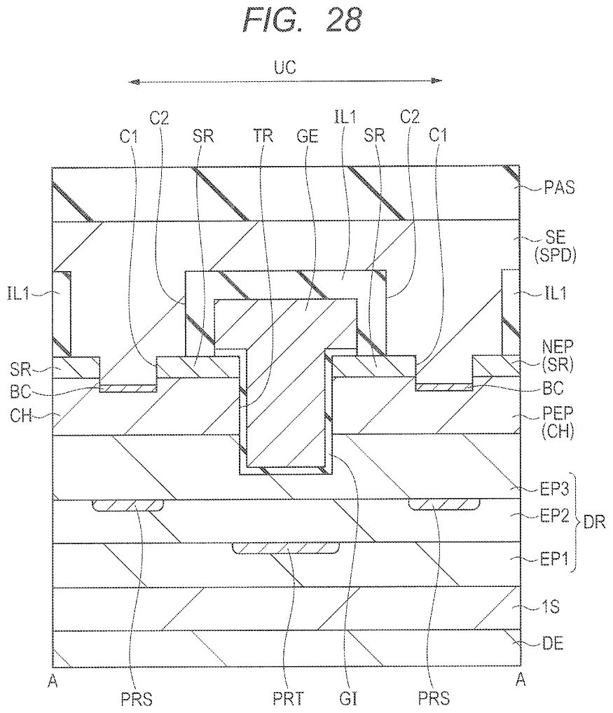

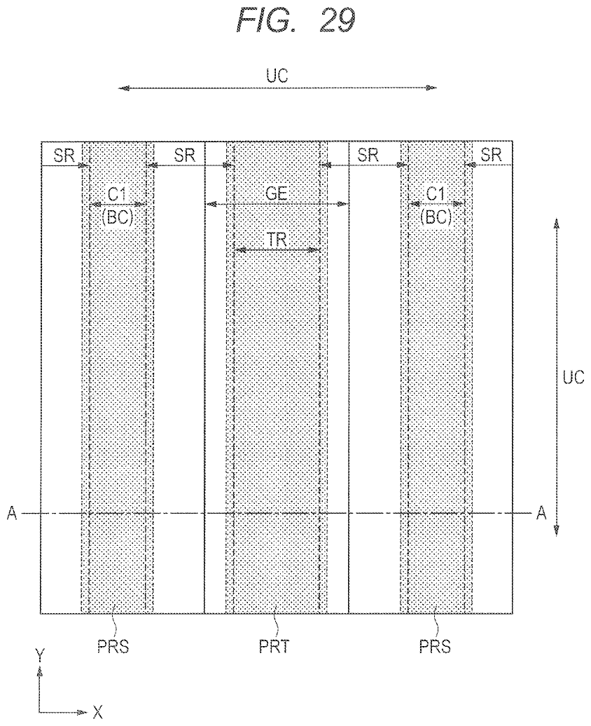

FIG. 28 is a cross-sectional view showing the configuration of a semiconductor device according to this embodiment. FIG. 29 is a plan view showing the configuration of the semiconductor device according to this embodiment. FIG. 28 corresponds to the cross-sectional view along a line A-A in FIG. 29. The semiconductor device shown in FIG. 28 and the like is a trench gate power transistor.

As shown in FIG. 28, the semiconductor device according to this embodiment includes a drift layer (drain region) DR arranged on the front face (first face) side of the SiC substrate 1S, a channel layer CH arranged over the drift layer DR, and a source region SR arranged over the channel layer CH. The drift layer DR includes the n-type semiconductor region, the channel layer CH includes the p-type semiconductor region, and the source region SR includes the n-type semiconductor region. These semiconductor regions include SiC, in which the p-type semiconductor region includes a p-type impurity and the n-type semiconductor region includes an n-type impurity. Moreover, the semiconductor regions can include either n-type or p-type epitaxial layer, as described later.

The semiconductor device according to the embodiment includes the gate electrode GE arranged via the gate insulating film GI in the trench TR penetrating the source region SR and the channel layer CH to reach the drift layer DR. The gate electrode GE fills the trench TR and extends to overlap a part of the source region SR as seen from above (see FIG. 29), having a “T-shaped” cross section.

Arranged at an end opposite from the other end of the source region SR in contact with the trench TR are contact holes (C1, C2) reaching the channel layer CH. Here, as for the contact holes (C1, C2), one with a larger width is referred to as the contact hole C2 and one with a smaller width is referred to as the contact hole C1. Formed over the bottom face of the contact holes (C1, C2) is a body contact region BC. The body contact region BC includes the p-type semiconductor region with impurity concentration higher than that of the channel layer CH, and it is formed to ensure ohmic contact between the source electrode SE and the channel layer CH.

Moreover, the interlayer insulating film IL1 is formed over the gate electrode GE. The interlayer insulating film IL1 includes an insulating film such as a silicon oxide film. The source electrode SE is arranged over the interlayer insulating film IL1 and inside the contact holes (C1, C2). The source electrode SE is configured by a conductive film. It is to be noted that, in some cases, a portion of the source electrode SE located inside the contact holes (C1, C2) may be referred to as a plug (via) and a portion thereof extending over the interlayer insulating film IL1 may be referred to as a wiring. The source electrode SE is electrically coupled to the body contact region BC and the source region SR. Formed over the source electrode SE is the passivation film PAS configured by the insulating film. It is to be noted that the drain electrode DE is formed on the rear face (second face) side of the SiC substrate 1S.

Here, in this embodiment, the drift layer DR includes a stack of the first drift epitaxial layer EP1, the second drift epitaxial layer EP2 formed thereover, and a third drift epitaxial layer EP3 formed thereover. The p-type semiconductor region PRT serving as a buried layer is arranged at the boundary between the first drift epitaxial layer EP1 and the second drift epitaxial layer EP2, and the p-type semiconductor region PRS serving as a buried layer is arranged at the boundary between the second drift epitaxial layer EP2 and the third drift epitaxial layer EP3.

That is, the p-type semiconductor region PRT is arranged at a location deeper than the p-type semiconductor region PRS. The p-type semiconductor regions (PRS, PRT) extend linearly in the Y direction (in the depth direction in FIG. 28) like the trench TR and the gate electrode GE (FIG. 29).

Thus, by providing the p-type semiconductor regions (PRS, PRT), it is possible to increase the breakdown voltage of the gate insulating film GI. Moreover, by arranging the p-type semiconductor region PRT at the location deeper than the p-type semiconductor region PRS, it is possible to ensure an electric current path (electric current path) and to reduce the specific on-resistance. Especially, because an inhibiting factor of the electric current path (electric current path) leading to increase of the specific on-resistance is larger in the p-type semiconductor region PRT below the trench TR than in the p-type semiconductor region PRS, it is preferable to arrange the p-type semiconductor region PRT at a deeper location.

### <Operation>

An operation of the semiconductor device (transistor) according to this embodiment is substantially the same as that in the first embodiment.

### [Description of Manufacturing Method]

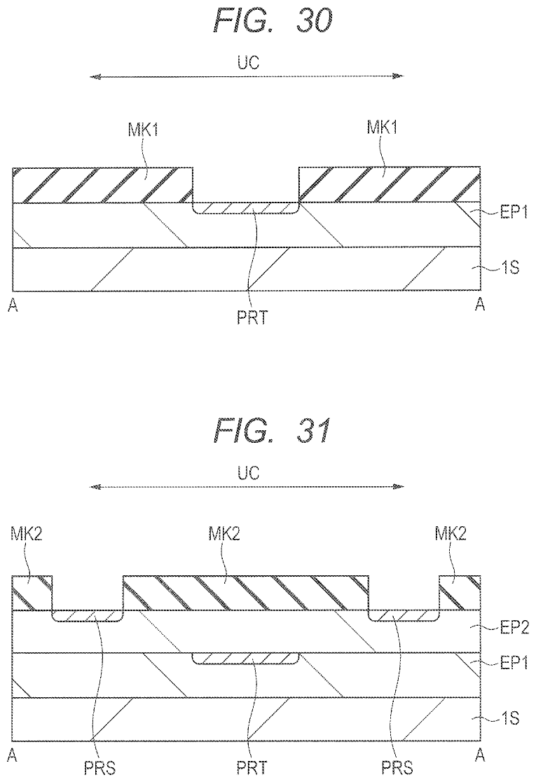

Next, a method of manufacturing the semiconductor device according to the embodiment is described and the configuration thereof is further clarified with reference to FIGS. 30 to 34. FIGS. 30 to 34 are cross-sectional views showing a manufacturing process of the semiconductor device according to the embodiment.

First, the SiC substrate 1S including the first drift epitaxial layer EP1 formed thereon as shown in FIG. 30 is provided.

Although there is no limitation to the method of forming the epitaxial layer over the SiC substrate 1S, it can be formed in the following manner. For example, the first drift epitaxial layer EP1 is formed by growing the epitaxial layer (n-type epitaxial layer) including SiC while introducing an n-type impurity such as nitrogen (N) and phosphorus (P) over the SiC substrate 1S.

Next, the p-type semiconductor region PRT is formed. For example, the mask film MK having an opening in the region where the p-type semiconductor region PRT is formed is formed over the first drift epitaxial layer EP1 using the photolithography technique and the etching technique. A silicon oxide film may be used as the mask film MK, for example.

Subsequently, the p-type semiconductor region PRT is formed over a surface of the first drift epitaxial layer EP1 by ion-implanting the p-type impurity such as aluminum (Al) or boron (B) using the mask film MK as a mask.

The p-type semiconductor region PRT extends linearly in the Y direction (see FIG. 29). In other words, it extends linearly in the Y direction in the unit cell UC (see FIG. 29). The mask film MK1 is then removed.

Next, as shown in FIG. 31, the second drift epitaxial layer EP2 is formed, and the p-type semiconductor region PRS is further formed. For example, the second drift epitaxial layer EP2 is formed by growing the epitaxial layer (n-type epitaxial layer) including SiC while introducing the n-type impurity such as nitrogen (N) and phosphorus (P) over the first drift epitaxial layer EP1 and the p-type semiconductor region PRT.

Then, for example, a mask film MK2 having an opening in a region where the p-type semiconductor region PRS is formed is formed over the second drift epitaxial layer EP2 using the photolithography technique and the etching technique. A silicon oxide film may be used as the mask film MK, for example.

The p-type semiconductor region PRS is then formed over a surface of the second drift epitaxial layer EP2 by ion-implanting the p-type impurity such as aluminum (Al) or boron (B) using the mask film MK2 as the mask.

The p-type semiconductor region PRS extends linearly in the Y direction (see FIG. 29). In other words, it extends linearly in the Y direction in the unit cell UC (see FIG. 29). The mask film MK2 is then removed.

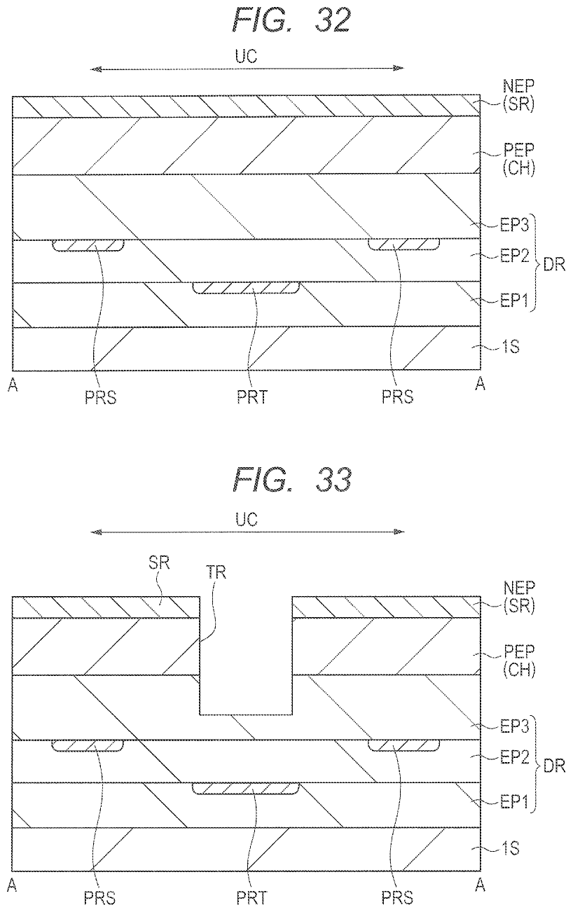

Next, as shown in FIG. 32, the third drift epitaxial layer EP3 is formed. For example, the third drift epitaxial layer EP3 is formed by growing the epitaxial layer (n-type epitaxial layer) including SiC while introducing the n-type impurity such as nitrogen (N) and phosphorus (P) over the second drift epitaxial layer EP2 and the p-type semiconductor region PRS. This allows for forming the drift layer DR configured by the stack of the first drift epitaxial layer EP1, the second drift epitaxial layer EP2, and the third drift epitaxial layer EP3. Moreover, the p-type semiconductor regions (PRS, PRT) are to be arranged inside the drift layer DR. Specifically, the p-type semiconductor region PRT is arranged near the boundary between the first drift epitaxial layer EP1 and the second drift epitaxial layer EP2, and the p-type semiconductor region PRS is arranged near the boundary between the second drift epitaxial layer EP2 and the third drift epitaxial layer EP3.

The p-type epitaxial layer PEP serving as the channel layer CH and the n-type epitaxial layer NEP serving as the source region SR are then formed in the same manner as the first embodiment.

Subsequently, as shown in FIG. 33, the trench TR is formed penetrating the n-type epitaxial layer (source region SR) NEP and the p-type epitaxial layer (channel layer CH) PEP to reach the third drift epitaxial layer EP3.

For example, the hard mask (not shown) having the opening in the region where the trench TR is formed is formed over then-type epitaxial layer (source region SR) NEP using the photolithography technique and the etching technique. Then, the trench TR is formed by etching the top of the n-type epitaxial layer (source region SR) NEP, the p-type epitaxial layer (channel layer CH) PEP, and the third drift epitaxial layer EP3 using the hard mask (not shown) as the mask. The hard mask (not shown) is then removed. The third drift epitaxial layer EP3, the p-type epitaxial layer (channel layer CH) PEP, and the n-type epitaxial layer (source region SR) NEP are exposed on the side face of the trench TR in this order from bottom to top. Moreover, the third drift epitaxial layer EP3 is exposed on the bottom face of the trench TR. Here, the p-type semiconductor region PRS is arranged at a location deeper than the bottom face of the trench TR and the p-type semiconductor region PRT is arranged at a location deeper than the p-type semiconductor region PRS.

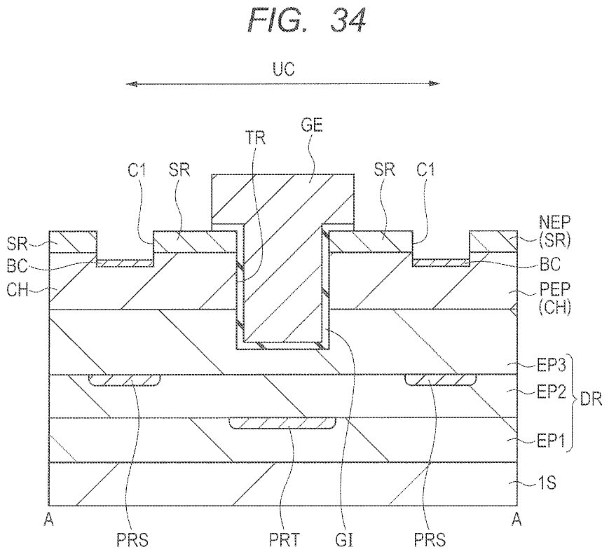

Next, as shown in FIG. 34, the contact hole C1 is formed in the n-type epitaxial layer (source region SR) NEP on both sides of the trench TR, and the body contact region BC is formed below the bottom face of the contact hole C1. The contact hole C1 and the body contact region BC can be formed in the same manner as the first embodiment.

Next, for example, the gate electrode GE is formed in the trench TR via the gate insulating film GI. The gate insulating film GI and the gate electrode GE can be formed in the same manner as the first embodiment.

Thereafter, the source electrode SE, the gate line GL, the gate pad GPD, and the like are formed in the same manner as the first embodiment (see FIGS. 28 and 3B). Then, in the same manner as the first embodiment, the passivation film PAS is formed so as to cover the source electrode SE, the gate line GL, and the gate pad GPD, and after the SiC substrate 1S is thinned, the drain electrode DE is formed.

The semiconductor device according to the embodiment can be formed in the above-described process.

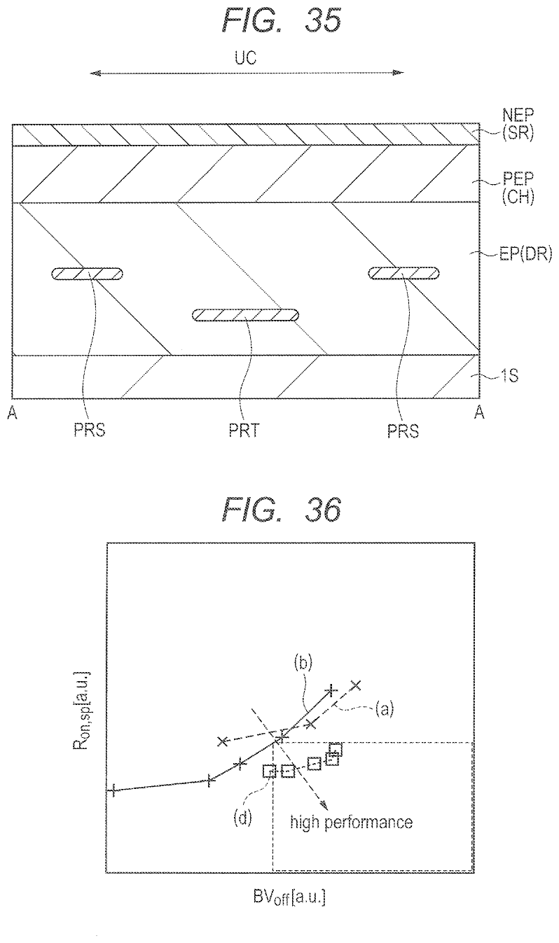

It is to be noted that, although the drift layer DR is configured by the stack of the first drift epitaxial layer EP1, the second drift epitaxial layer EP2, and the third drift epitaxial layer EP3 in the above-mentioned process, the drift layer DR may be a single-layered epitaxial layer EP and the p-type semiconductor regions (PRS, PRT) may be provided therein by deep ion implantation, as shown in FIG. 35. FIG. 35 is a cross-sectional view showing another manufacturing process of the semiconductor device according to the embodiment. As described above, according to the embodiment, it is possible to reduce the specific on-resistance while maintaining the breakdown voltage of the gate insulating film GI by providing the p-type semiconductor regions (PRS, PRT) and further by forming the p-type semiconductor regions (PRS, PRT) at different heights.

FIG. 36 is a graph showing a relationship between the breakdown voltage and the specific on-resistance of the semiconductor devices according to the first and second comparison examples and the third embodiment. The abscissa indicates the breakdown voltage (BV_{off}, [a.u.]), and the ordinate indicates the specific on-resistance (R_{on,sp}, [a.u.]). A curve (a) indicates the second comparison example described in the first embodiment, a curve (b) indicates the first comparison example escribed in the first embodiment, and a curve (d) indicates the present embodiment.

As shown in FIG. 36, performance increases (high performance) towards the bottom right region of the graph, i.e. in the direction of the arrow in the drawing. In other words, for example, in the region surrounded by the broken line, the breakdown voltage is high and the specific on-resistance is low. As can be seen from FIG. 36, in the first comparison example (curve (b)) and the second comparison example (curve (a)), it is not possible to achieve the high breakdown voltage and the low specific on-resistance in the region surrounded by the broken line no matter how the values are adjusted. To the contrary, in this embodiment (curve (d)), it is possible to achieve the high breakdown voltage and the low specific on-resistance in the region surrounded by the broken line. Moreover, it can be seen that the curve (d) tends to shift in the direction of the arrow in the drawing compared to the curves (a) and (b) and that the specific on-resistance can be reduced while maintaining the breakdown voltage in the embodiment.

In this manner, it is possible to reduce the specific on-resistance while maintaining the breakdown voltage in this embodiment.

It is to be noted that, although the p-type semiconductor regions (PRS, PRT) extend linearly in the Y direction in this embodiment as shown in FIG. 29, the p-type semiconductor regions (PRS, PRT) may be provided with the space SP.

That is, the p-type semiconductor region PRS may be provided with the space SP while differentiating the height of the p-type semiconductor regions PRS and PRT (see FIG. 2). The p-type semiconductor regions PRT may also be provided with the space SP while differentiating the height of the p-type semiconductor regions PRS and PRT (see FIG. 24). Furthermore, both the p-type semiconductor regions PRS and PRT may also be provided with the spaces SP, respectively, while differentiating the height of the p-type semiconductor regions PRS and PRT (see FIG. 25).

### Fourth Embodiment

In this embodiment, modification examples are described.

### First Modification Example

Although the trench TR (gate electrode GE) is arranged linearly in the Y direction in the first application example of the second embodiment (FIG. 24), it is also possible to extend the trench TR (gate electrode GE) in the Y direction and the X direction so as to have an intersection.

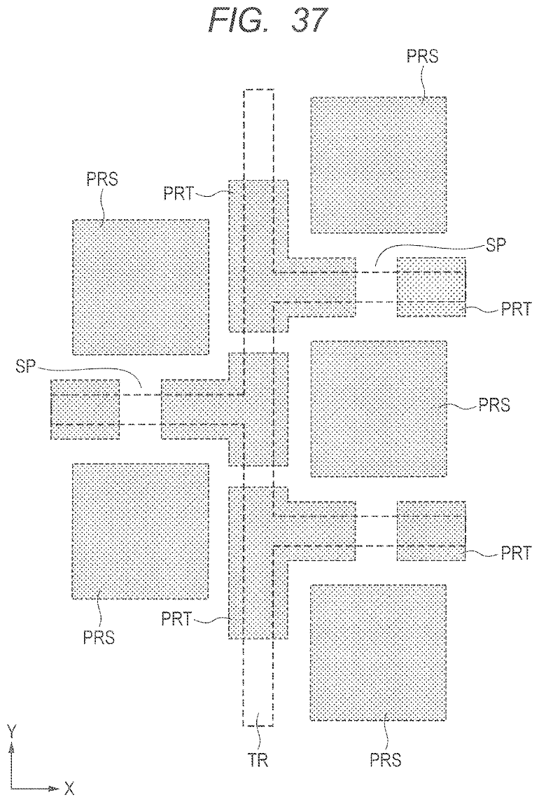

FIG. 37 is a plan view showing a configuration of a semiconductor device according to a first modification example of a fourth embodiment. In the modification example, the configuration is the same as that of the first embodiment (FIGS. 1, 2, and the like) except the trench TR (gate electrode GE) and the region where the p-type semiconductor regions (PRS, PRT) are formed.

In the modification example, the trench TR (gate electrode GE) includes a portion extending in the Y direction and a portion extending in the X direction. The portion extending in the Y direction and the portion extending in the X direction are arranged in an alternating manner.

Although the p-type semiconductor region PRT is arranged in the direction in which the trench TR (gate electrode GE) extends, a portion thereof is thinned out. The region where the p-type semiconductor region PRT is thinned out becomes the space SP.

It should be noted that, however, the p-type semiconductor region PRT is always arranged below the intersection of the trench TR (gate electrode GE). In other words, the space SP is not arranged below the intersection of the trench TR (gate electrode GE).

The p-type semiconductor region PRS is arranged on both sides of the portion of the trench TR (gate electrode GE) extending in the X direction. The plane shape of the p-type semiconductor region PRS is rectangular.

### Second Modification Example

Although the trench TR (gate electrode GE) extend linearly in the Y direction in the first application example of the second embodiment (FIG. 24), it is also possible to extend the trench TR (gate electrode GE) in the Y direction and the X direction so as to have an intersection.

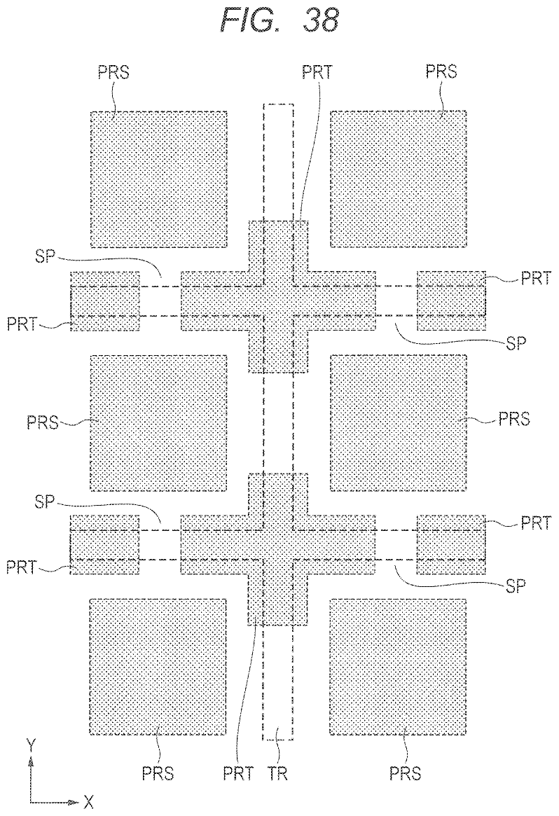

FIG. 38 is a plan view showing a configuration of a semiconductor device according to a second modification example of the fourth embodiment. In the modification example, the configuration is the same as that of the first embodiment (FIGS. 1, 2, and the like) except the trench TR (gate electrode GE) and the region where the p-type semiconductor regions (PRS, PRT) are formed.

In the modification example, the trench TR (gate electrode GE) includes the portion extending in the Y direction and the portion extending in the X direction. The portion extending in the Y direction and the portion extending in the X direction are arranged to intersect crosswise.

Although the p-type semiconductor region PRT is arranged in the direction in which the trench TR (gate electrode GE) extends, a portion thereof is thinned out. The region where the p-type semiconductor region PRT is thinned out becomes the space SP.

It should be noted that, however, the p-type semiconductor region PRT is always arranged below the intersection of the trench TR (gate electrode GE). In other words, the space SP is not arranged below the intersection of the trench TR (gate electrode GE).

The p-type semiconductor region PRS is arranged on both sides of the portion of the trench TR (gate electrode GE) extending in the X direction. The plane shape of the p-type semiconductor region PRS is rectangular.

### Third Modification Example

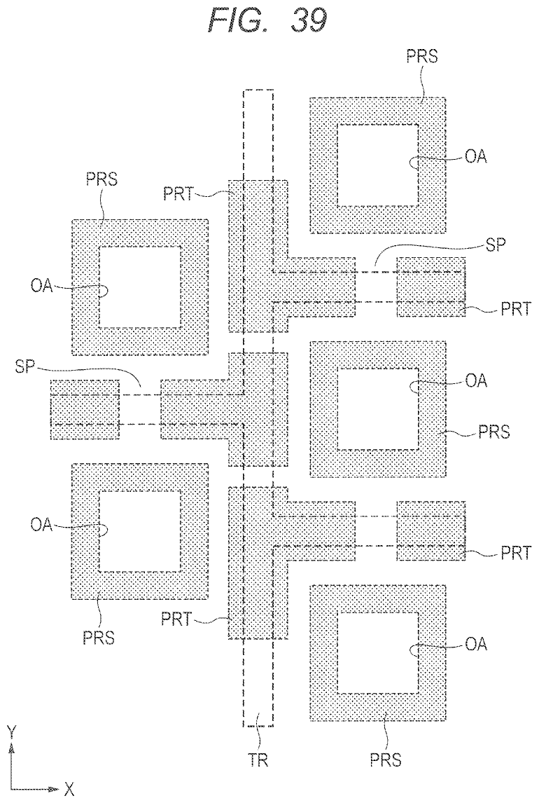

In the above-mentioned first modification example, the p-type semiconductor region PRS may be provided with an opening OA (FIG. 39). In other words, the p-type semiconductor region PRS may have an annular rectangular shape. FIG. 39 is a plan view showing a configuration of a semiconductor device according to a third modification example of the embodiment.

### Fourth Modification Example

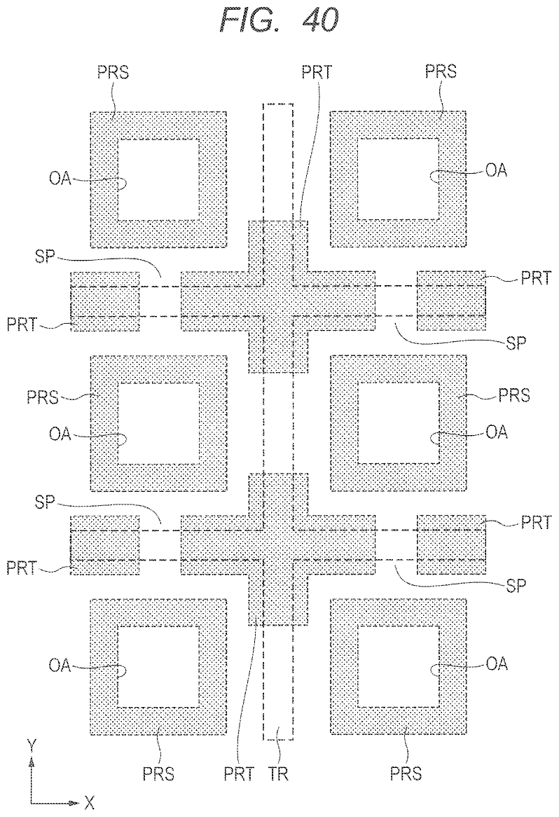

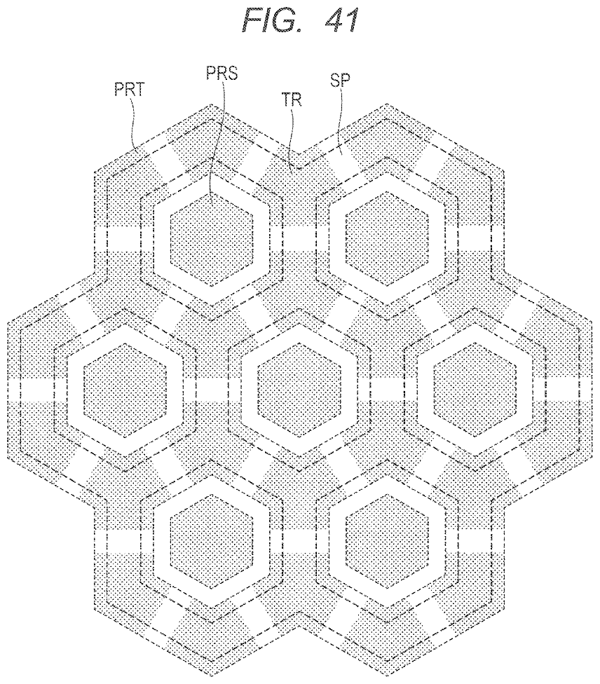

In the above-mentioned second modification example, the p-type semiconductor region PRS may be provided with the opening OA (FIG. 40). In other words, the p-type semiconductor region PRS may have an annular rectangular shape. FIG. 40 is a plan view showing a configuration of a semiconductor device according to a fourth modification example of the embodiment.

### Fifth Modification Example

Although the portion extending in the X direction and the portion extending in the Y direction of the trench TR (gate electrode GE) intersect at 90 degrees in the above-mentioned first and second modification examples and the like, the trench TR (gate electrode GE) may have a polygonal shape.

FIG. 41 is a plan view showing a configuration of a semiconductor device according to a fifth modification example of the embodiment. In FIG. 41, the trench TR (gate electrode GE) is arranged in a hexagonal shape as seen from above. In this case, a portion of the trench TR (gate electrode GE) extending in one direction intersects another portion extending in another direction crossing the one direction are to intersect at 120 degrees.

Even in such a case, the p-type semiconductor region PRT may be arranged in the direction in which the trench TR (gate electrode GE) extends and a portion thereof may be thinned out to provide the space SP. Moreover, the plane shape of the p-type semiconductor region PRS arranged on both sides of the trench TR (gate electrode GE) may be hexagonal.

### Sixth Modification Example

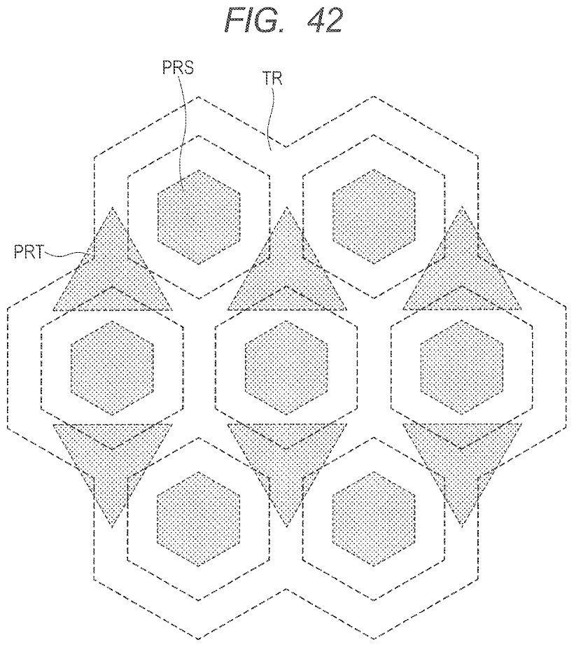

In the above-mentioned fifth modification example, the p-type semiconductor region PRT may be arranged below an intersection of a first portion of the trench TR (gate electrode GE) extending in a first direction, a second portion thereof crossing the first portion at 120 degrees, and a third portion thereof crossing the second portion at 120 degrees. In this case, the plane shape of the p-type semiconductor region PRT may be, for example, triangular (FIG. 42). FIG. 42 is a plan view showing a configuration of a semiconductor device according to a sixth modification example of the embodiment.

### Seventh Modification Example

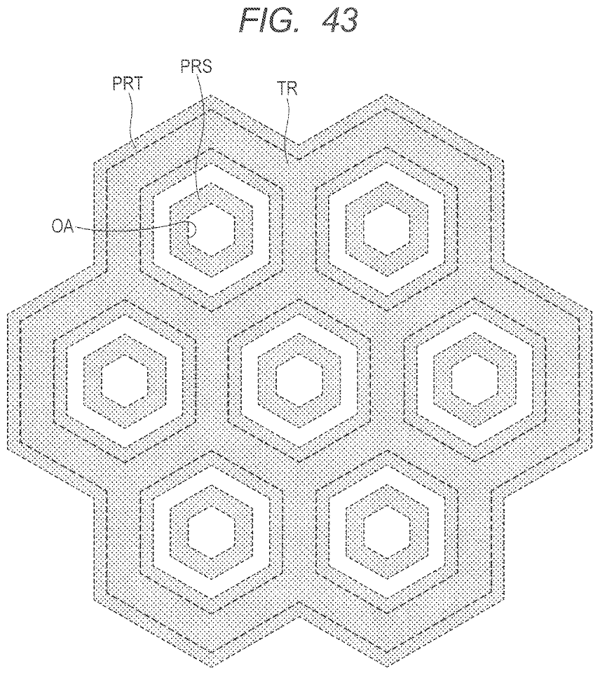

In the above-mentioned fifth modification example, the p-type semiconductor region PRS may be provided with the opening OA (FIG. 43). In other words, the p-type semiconductor region PRS may have an annular hexagonal shape. FIG. 43 is a plan view showing a configuration of a semiconductor device according to a seventh modification example of the embodiment.

### Eighth Modification Example

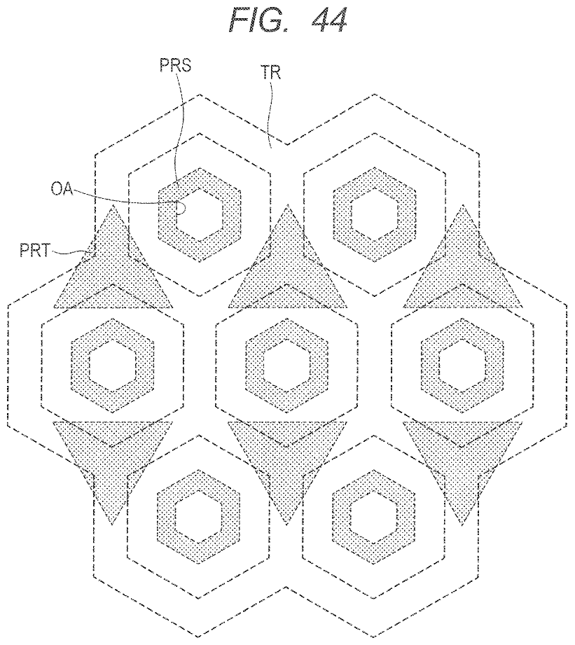

In the above-mentioned sixth modification example, the p-type semiconductor region PRS may be provided with the opening OA (FIG. 44). In other words, the p-type semiconductor region PRS may have an annular hexagonal shape. FIG. 44 is a plan view showing a configuration of a semiconductor device according to an eighth modification example of the embodiment.

Although the invention made by the inventors are specifically described with reference to the embodiments, it is needless to say that the invention is not limited to the embodiments but various modifications may be made without departing from the scope of the invention.

For example, the above-mentioned embodiments, application examples, and modification examples may be combined appropriately. In addition, the n-type transistor may be replaced by a p-type transistor.

Moreover, although the above-mentioned embodiments are described taking an example of the trench gate power transistor including SiC, the configuration of the embodiments may be applied to a trench gate power transistor including Si. It is to be noted that, however, as described above, because SiC has a larger bandgap compared to silicon (Si), high breakdown voltage of the SiC itself can be secured but it is more important to increase breakdown voltage of other components that include another material (such as a gate insulating film). Accordingly, the above-mentioned embodiments may be more effective when applied to the trench gate power transistor including SiC.

### (Supplementary Note 1)

A semiconductor device including:

a drift layer formed over a semiconductor substrate;

a channel layer formed over the drift layer;

a source region formed over the channel layer;

a trench penetrating the channel layer to reach the drift layer and contacting the source region;

a gate insulating film formed over an inner wall of the trench;

a gate electrode that fills the trench;

a first semiconductor region formed in a position overlapping a region where the trench is formed as seen from above in the drift layer below the trench and having an impurity of a conductivity type opposite from that of the drift layer; and

a second semiconductor region spaced from the region where the trench is formed as seen from above in the drift layer below the trench and having an impurity of the conductivity type opposite from that of the drift layer,

in which the trench includes a first portion extending in a first direction and a second portion extending in a second direction crossing the first direction,

in which the first semiconductor region and the second semiconductor region extend along the region where the trench is formed, and

in which the first semiconductor region is configured by a plurality of first regions arranged at a first space.

### (Supplementary Note 2)

The semiconductor device according to Supplementary Note 1, further including:

an intersection of the first portion and the second portion,

in which the first region is arranged to overlap the intersection as seen from above.

### (Supplementary Note 3)

The semiconductor device according to Supplementary Note 1,

in which the second semiconductor region is configured by a plurality of first regions arranged at a first space, and

in which the second region includes an opening.

### (Supplementary Note 4)

The semiconductor device according to Supplementary Note 2,

in which a crossing angle of the first portion and the second portion at the intersection is 90 degrees.

### (Supplementary Note 5)

The semiconductor device according to Supplementary Note 2,

in which a crossing angle of the first portion and the second portion at the intersection is 120 degrees.

### (Supplementary Note 6)

The semiconductor device according to Supplementary Note 1,

in which the drift layer, the channel layer, and the source region are configured by SiC.

### (Supplementary Note 7)

What is claimed is:

1. A method of manufacturing a semiconductor device, comprising the steps of:
(a) forming a drift layer over a semiconductor substrate;
(b) forming a channel layer over the drift layer;
(c) forming a source region over the channel layer;
(d) forming a trench penetrating the channel layer to reach the drift layer and contacting the source region;
(e) forming a gate insulating film over an inner wall of the trench; and
(f) forming agate electrode that fills the trench over the gate insulating film,
in which the step (a) includes the steps of forming:
a first semiconductor region formed in a position overlapping a region where the trench is formed as seen from above in the drift layer and having an impurity of a conductivity type opposite from that of the drift layer; and
a second semiconductor region spaced from the region where the trench is formed as seen from above in the drift layer and having an impurity of the conductivity type opposite from that of the drift layer, the second semiconductor region being configured by a plurality of second regions arranged at a second space along the region where the trench is formed.

2. The method of manufacturing a semiconductor device according to claim 1,
in which the step (a) includes the steps of:
(a1) after forming a first drift layer, forming a first semiconductor region and a second semiconductor region over a surface of the first drift layer by ion implantation; and
(a2) forming a second drift layer over the first drift layer.

3. The method of manufacturing a semiconductor device according to claim 1,
in which the step (a) includes the step of:
(a1) after forming the drift layer, forming a first semiconductor region and a second semiconductor region in the middle of the drift layer by ion implantation.

4. A method of manufacturing a semiconductor device, comprising the steps of:
(a) forming a drift layer over a semiconductor substrate;
(b) forming a channel layer over the drift layer;
(c) forming a source region over the channel layer;
(d) forming a trench penetrating the channel layer to reach the drift layer and contacting the source region;
(e) forming a gate insulating film over an inner wall of the trench; and
(f) forming agate electrode that fills the trench over the gate insulating film,
in which the step (a) includes the steps of forming:
a first semiconductor region formed in a position overlapping a region where the trench is formed as seen from above in the drift layer and having an impurity of a conductivity type opposite from that of the drift layer; and
a second semiconductor region spaced from the region where the trench is formed as seen from above in the drift layer and having an impurity of the conductivity type opposite from that of the drift layer, the second semiconductor region being arranged at a location shallower than the first semiconductor region.
